(19) United States
(12) Patent Application Publication
(10) Pub. No.: US 2026/0027596 A1
(43) Pub. Date: Jan. 29, 2026

(54) PROCESSING SYSTEM

(71) Applicant: Tokyo Electron Limited, Tokyo (JP)

(72) Inventor: Kento TOKAIRIN, Miyagi (JP)

(73) Assignee: Tokyo Electron Limited, Tokyo (JP)

(21) Appl. No.: 19/344,533

(22) Filed: Sep. 30, 2025

Related U.S. Application Data
(63) Continuation of application No. PCT/JP2024/013650, filed on Apr. 2, 2024.

(30) Foreign Application Priority Data
Apr. 14, 2023 (JP) 2023-066632

(51) Int. Cl. B08B 5/02; B08B 5/04; B08B 13/00; B25J 11/00; B25J 15/06; G06T 7/00; H01L 21/68; H01L 21/687

(52) U.S. Cl. CPC B08B 5/02; B08B 5/04; B08B 13/00; B25J 11/0095; B25J 15/0616; G06T 7/001; H01L 21/681; H01L 21/68707; G06T 2207/30164

(57) ABSTRACT

A processing system disclosed includes an atmosphere conveyance module, a conveyance device, and a cleaning device. The atmosphere conveyance module is capable of conveying a substrate in an atmosphere. The conveyance device includes an end effector including at least one support member on which the substrate is to be mounted. The conveyance device is provided in the atmosphere conveyance module and may convey the substrate. The cleaning device cleans the at least one support member.

### CROSS-REFERENCE TO RELATED APPLICATIONS

This application is a Continuation of PCT International Application No. PCT/JP2024/013650, filed on Apr. 2, 2024, which claims priority under 35 U.S.C. § 119(a) to Japanese Patent Application No. 2023-066632, filed in Japan on Apr. 14, 2023 each are hereby expressly incorporated by reference into the present application.

### TECHNICAL FIELD

An exemplary embodiment of the present disclosure relates to a processing system.

### BACKGROUND

A substrate conveyance device is used in a process of mounting a substrate on a substrate mount. The substrate conveyance device disclosed in Patent Literature 1 includes a hand, a substrate detector, and a control device. A substrate is mounted on the hand. The substrate detector is provided in the hand and projects light to the substrate. The control device determines whether or not the substrate positionally deviates by determining whether or not the substrate detector has received reflected light from a principal surface of the substrate.

### SUMMARY

### Technical Problem

The present disclosure provides a technology for cleaning a support member that supports a substrate in a conveyance device.

### Solutions to Problem

In one exemplary embodiment, a processing system is provided. The processing system includes an atmosphere conveyance module, a conveyance device, and a cleaning device. The atmosphere conveyance module is capable of conveying a substrate in an atmosphere. The conveyance device includes an end effector including at least one support member on which the substrate is configured to be mounted. The conveyance device is provided in the atmosphere conveyance module and is configured to convey the substrate. The cleaning device cleans the at least one support member.

### Advantageous Effect of Disclosure

According to one exemplary embodiment, a support member that supports a substrate in a conveyance device can be cleaned.

### BRIEF DESCRIPTION OF THE DRAWINGS

FIG. 1 is a side view showing a processing system according to one exemplary embodiment.

FIG. 2 is a diagram showing the processing system according to one exemplary embodiment.

FIG. 3 is a top view showing a conveyance robot of the processing system according to one exemplary embodiment.

FIG. 4 is a cross-sectional view of the conveyance robot and a substrate taken along line IV-IV of FIG. 3.

FIG. 5 is a flowchart of a cleaning method by the processing system according to one exemplary embodiment.

FIG. 6 is a flowchart of a suction force abnormality detection method by the processing system according to one exemplary embodiment.

FIG. 7 is a flowchart of a position adjustment method by the processing system according to one exemplary embodiment.

FIG. 8 is a flowchart of foreign matter removal method by the processing system according to one exemplary embodiment.

FIG. 9 is a flowchart of an image acquisition method by the processing system according to one exemplary embodiment.

FIG. 10 is a flowchart of a polishing method of the support member by the processing system according to one exemplary embodiment.

FIG. 11 is a flowchart of an abnormality detection method by the processing system according to one exemplary embodiment.

### DETAILED DESCRIPTION

Hereinafter, various exemplary embodiments will be described in detail with reference to the drawings. In each drawing, the same or equivalent parts are denoted by the same reference signs.

[Processing System]

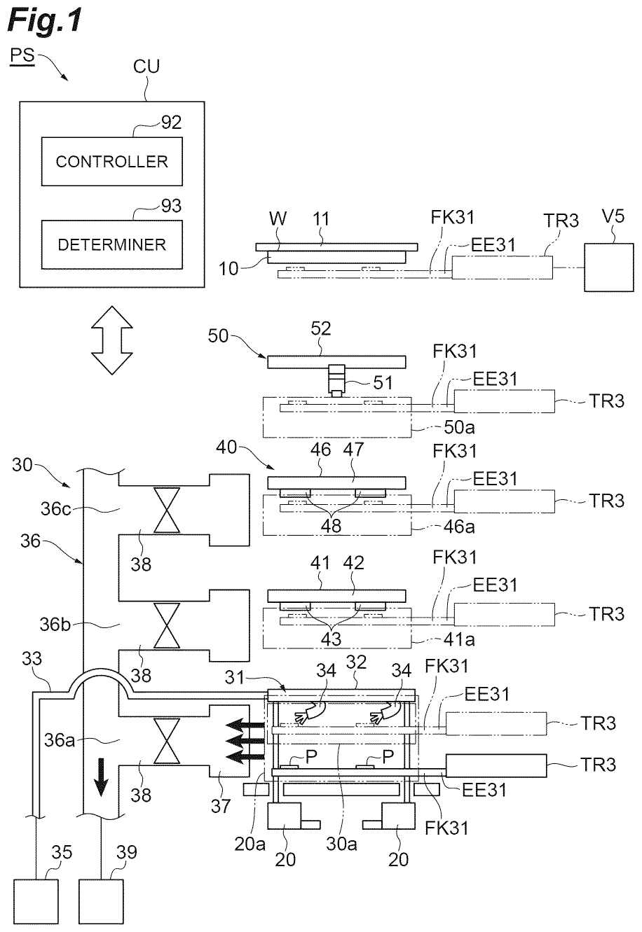

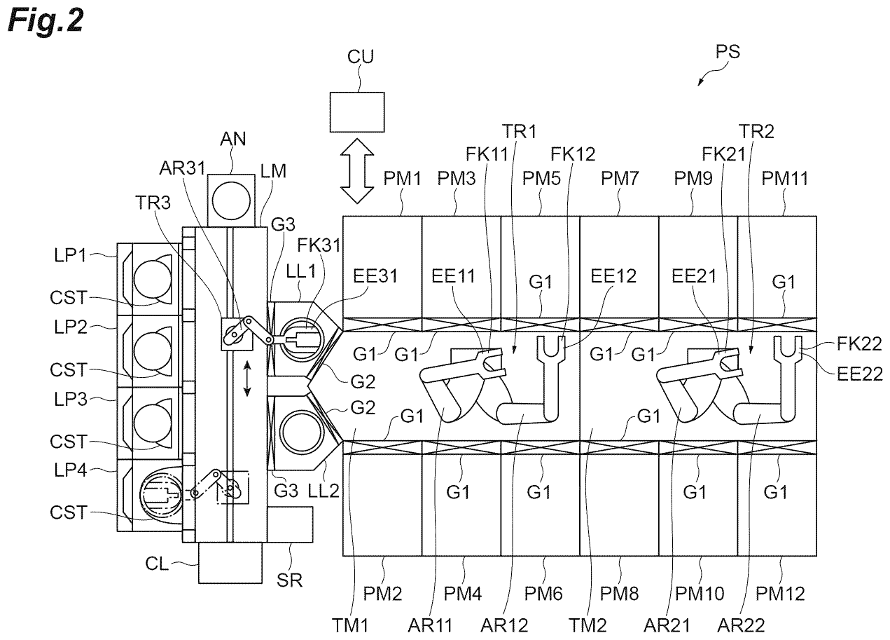

An example of a processing system according to one exemplary embodiment will be described with reference to FIGS. 1 and 2. FIG. 1 is a side view showing a part of the processing system according to one exemplary embodiment. FIG. 2 is a diagram showing the processing system according to one exemplary embodiment. A processing system PS is a system that conveys a substrate W by a conveyance robot TR3 and processes the substrate W. The conveyance robot TR3 is an example of a conveyance device. The processing system PS is configured to clean at least one support member P that supports the substrate W in the conveyance robot TR3. The processing system PS is a system configured to clean the at least one support member P supporting the substrate W in the conveyance robot TR3.

As shown in FIGS. 1 and 2, the processing system PS includes a loader module LM, the conveyance robot TR3, and a polishing device 40. The loader module LM is an example of an atmosphere conveyance module. The polishing device 40 is an example of a cleaning device. The processing system PS may further include an imaging device 50 and a control device CU. The processing system PS may further include at least one suction sensor V5, at least one position measurer 20, and a foreign matter removal device 30. The suction sensor V5 is an example of a pressure measurer.

As shown in FIG. 2, the processing system PS may further include a cleaning station CL. The position measurer 20, the foreign matter removal device 30, the polishing device 40, and the imaging device 50 shown in FIG. 1 are provided in the cleaning station CL.

As shown in FIG. 2, the processing system PS may further include load ports LP1 to LP4, an aligner AN, load lock modules LL1 and LL2, and a storage SR. The processing system PS may further include conveyance modules TM1 and TM2, process modules PM1 to PM12, and the like.

In the processing system PS, the loader module LM is configured to convey the substrate W in an atmosphere. The loader module LM is configured to convey the substrate W taken from any one of the load ports LP1 to LP4 in an atmospheric pressure environment. The loader module LM includes a chamber. A pressure in the chamber of the loader module LM is set to an atmospheric pressure. The loader module LM may include a fan filter unit (FFU). The loader module LM is, for example, an equipment front end module (EFEM). The loader module LM is disposed between each of the load ports LP1 to LP4 and each of the load lock modules LL1 and LL2. The load ports LP1 to LP4 are arranged along one of a pair of edges of the loader module LM along a longitudinal direction. The load lock modules LL1 and LL2 are arranged along the other of the pair of edges of the loader module LM along the longitudinal direction. Each of the load ports LP1 to LP4 is configured to support a cassette CST mounted thereon. The cassette CST is a container that accommodates a plurality of substrates W therein. The cassette CST is, for example, a front-opening unified pod (FOUP).

The loader module LM further includes the conveyance robot TR3. The conveyance robot TR3 is provided in the loader module LM. For example, the conveyance robot TR3 is provided in the chamber of the loader module LM. The conveyance robot TR3 includes, for example, an end effector EE31. The conveyance robot TR3 may include a multi-joint arm AR31. The conveyance robot TR3 conveys the substrate W by moving the end effector EE31 based on an operation instruction output by the control device CU (described later). The conveyance robot TR3 conveys the substrate W between any two of the load ports LP1 to LP4, the load lock modules LL1 and LL2, the aligner AN, the storage SR, and the cleaning station CL.

The aligner AN is connected to the loader module LM and is configured to adjust a position of the substrate W. In the example shown in FIG. 2, the aligner AN is disposed along one edge of a pair of edges of the loader module LM along a short direction.

The storage SR is connected to the loader module LM and is configured to store the substrate W therein. In the example shown in FIG. 2, the storage SR is disposed along the edge of the loader module LM along the longitudinal direction.

The cleaning station CL is configured to clean the at least one support member (described later) of the conveyance robot TR3. In the example shown in FIG. 2, the cleaning station CL is disposed along the other of the pair of edges of the loader module LM along the short direction, on which the aligner AN is not provided. The cleaning station CL is connected to the chamber of the loader module LM. The cleaning station CL may be disposed along the other edge of the pair of edges of the loader module LM along the short direction. The aligner AN is not provided on the other edge of the loader module LM. The cleaning station CL may be disposed along the edge of the loader module LM along the longitudinal direction. The cleaning station CL and the storage SR may be arranged in this order. A partition is not provided between the cleaning station CL and the loader module LM, and the cleaning station CL and the loader module LM communicate with each other. The conveyance robot TR3 positions the end effector EE31 in the cleaning station CL while positioning a part of the multi-joint arm AR31 in the loader module LM. The cleaning station CL will be described in detail later.

Each of the load lock modules LL1 and LL2 is connected to the loader module LM and provides a preliminary decompression chamber. Each of the load lock modules LL1 and LL2 is disposed between the conveyance module TM1 and the loader module LM. Each of the load lock modules LL1 and LL2 and the loader module LM are connected to each other via a gate valve G3. Each of the load lock modules LL1 and LL2 and the conveyance module TM1 are connected to each other via a gate valve G2.

Each of the load lock modules LL1 and LL2 includes a stage disposed in an internal space thereof. A pressure in the internal space can be reduced. The pressure in the internal space is set to the atmospheric pressure during conveyance of the substrate W between the internal space and the loader module LM. The pressure in the internal space is reduced to, for example, a vacuum state during conveyance of the substrate W between the internal space and the conveyance module TM1.

Each of the conveyance modules TM1 and TM2 includes a chamber. Each of the conveyance modules TM1 and TM2 is configured to convey the substrate W through a decompressed space in the chamber. The chamber of the conveyance module TM1 is connected to each of the load lock modules LL1 and LL2 via the gate valve G2. The process modules PM1 to PM6 are connected to the chamber of the conveyance module TM1 via a gate valve G1. The chamber of the conveyance module TM1 is connected to the chamber of the conveyance module TM2. The process modules PM7 to PM12 are connected to the chamber of the conveyance module TM2 via the gate valve G1.

The conveyance module TM1 includes a conveyance robot TR1 provided in the chamber thereof. The conveyance robot TR1 includes, for example, end effectors EE11 and EE12 and multi-joint arms AR11 and AR12. The end effector EE11 includes a fork FK11. The end effector EE12 includes a fork FK12. The fork FK11 is attached to a tip end of the multi-joint arm AR11 and is configured to support the substrate W mounted thereon. The fork FK12 is attached to a tip end of the multi-joint arm AR12 and is configured to support the substrate W mounted thereon. The conveyance robot TR1 conveys the substrate W based on the operation instruction output from the control device CU (described later). The conveyance robot TR1 holds the substrate W by the forks FK11 and FK12. The conveyance robot TR1 conveys the substrate W between any two of the load lock modules LL1 and LL2, the process modules PM1 to PM6, the chamber of the conveyance module TM1, and a path between the chamber of the conveyance module TM1 and the chamber of the conveyance module TM2.

The conveyance module TM2 includes a conveyance robot TR2 provided in the chamber thereof. The conveyance robot TR2 includes, for example, end effectors EE21 and EE22 and multi-joint arms AR21 and AR22. The end effector EE21 includes a fork FK21. The end effector EE22 includes a fork FK22. The fork FK21 is attached to a tip end of the multi-joint arm AR21 and is configured to support the substrate W mounted thereon. The fork FK22 is attached to a tip end of the multi-joint arm AR22 and is configured to support the substrate W mounted thereon. The conveyance robot TR2 conveys the substrate W based on the operation instruction output from the control device CU (described later). The conveyance robot TR2 holds the substrate W by the forks FK21 and FK22. The conveyance robot TR2 conveys the substrate W between any two of the process modules PM7 to PM12 and the above path.

Each of the process modules PM1 to PM12 is a substrate processing device configured to perform dedicated processing on the substrate W. At least one of the process modules PM1 to PM12 may be a plasma processing device. The conveyance modules TM1 and TM2 and the process modules PM1 to PM12 are partitioned by the gate valve G1 that is openable and closable.

The control device CU is, for example, a computer. The control device CU includes a central processing unit (CPU), a random access memory (RAM), a read only memory (ROM), an auxiliary storage device, and the like. The CPU operates based on a program stored in the ROM or the auxiliary storage device and controls each part of the processing system PS. For example, the control device CU outputs the operation instruction to the conveyance robots TR1, TR2, and TR3 and the like. The operation instruction includes an instruction to move the end effectors EE11, EE12, EE21, EE22, and EE31 that convey the substrate W, to a location to which the substrate W is conveyed. The operation instruction includes an instruction to move the end effector EE31 to each configuration in the cleaning station CL.

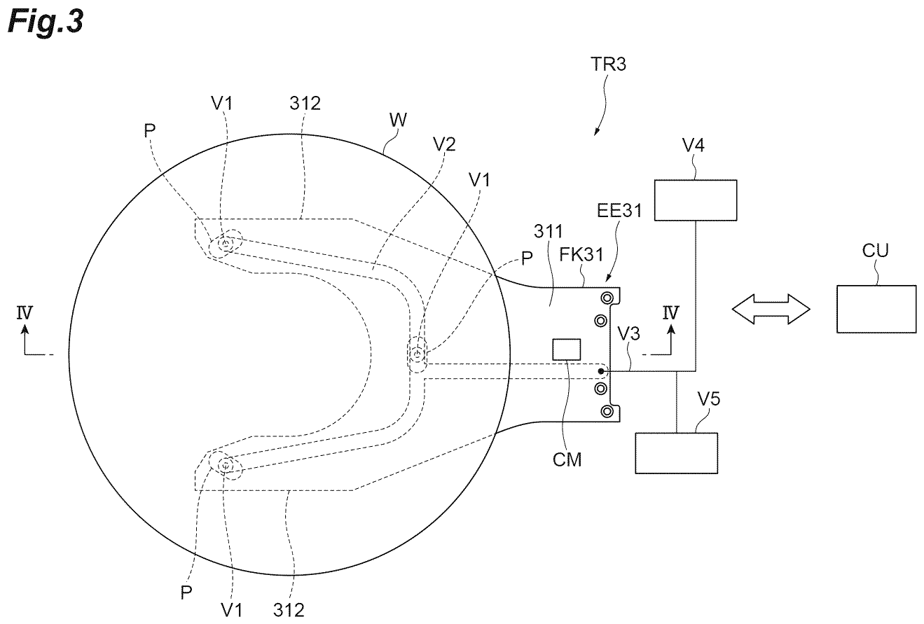

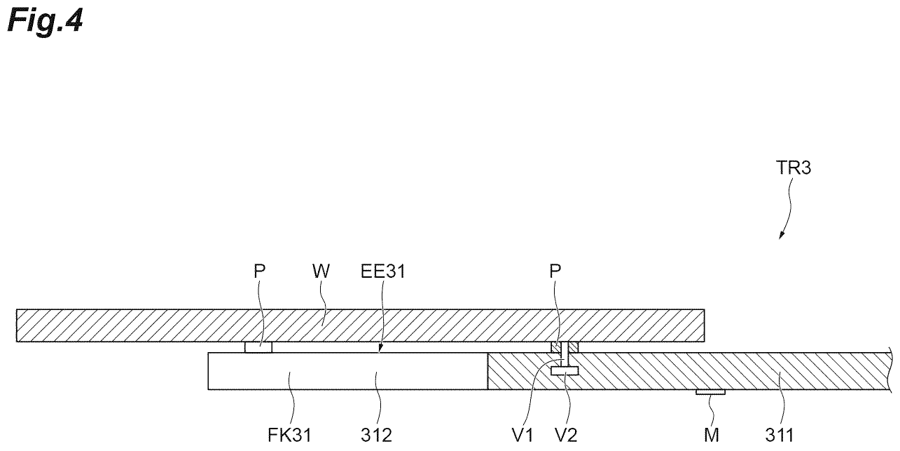

The processing system PS is not necessarily limited to the one shown in FIG. 2. For example, the number of process modules and/or the number of forks in the processing system may be different from those shown in FIG. 2. The processing system may be a system (a so-called loader type system) in which a plurality of module groups each including a process module and a load lock module are connected to a loader module. Alternatively, the processing system may be a system (a so-called cluster type system) in which two or more process modules are connected to be arranged around a conveyance module to surround the conveyance module. Hereinafter, each configuration of the processing system according to one exemplary embodiment will be described in detail. First, details of each configuration in the conveyance robot TR3 will be described with reference to FIGS. 3 and 4. FIG. 3 is a top view showing the conveyance robot of the processing system according to one exemplary embodiment. FIG. 4 is a cross-sectional view of the conveyance robot and the substrate along line IV-IV of FIG. 3.

The end effector EE31 of the conveyance robot TR3 includes a fork FK31 and the at least one support member P. The fork FK31 includes a base end 311 and a pair of arms 312 and 312. The pair of arms 312 and 312 are separated from each other and extend from the base end 311 to tip ends thereof. That is, the fork FK31 has a substantially U-shape or a horseshoe shape. A width of a gap between the arm 312 and the arm 312 is larger than a width of a substrate mount 10 so that the pair of arms 312 and 312 do not come into contact with the substrate mount 10 during upward and downward movement of the end effector EE31. The end effector EE31 further includes a camera CM. The camera CM images the at least one support member P of the end effector EE31 and the substrate W on the at least one support member P. The camera CM provides notification of a captured image to a determiner 93 (i.e., determiner circuitry) of the control device CU.

The substrate W is configured to be mounted on the at least one support member P. A material of the at least one support member P may be engineering plastic, particularly polyimide. Vespel (registered trademark) may be used as polyimide as the material of the at least one support member P. The material of the at least one support member P is not limited to polyimide and only needs to be a material having predetermined anti-corrosion properties, heat resistance properties, and strength. The end effector EE31 may include three support members P as the at least one support member P. The three support members P are provided on the fork FK31. Three markers M may be provided on a surface of the fork FK31 opposite to a surface on which the three support members P are provided. The markers M are targets when the at least one position measurer 20 aligns a position of the end effector EE31 with the foreign matter removal device 30, the polishing device 40, and the imaging device 50.

The three support members P are, for example, suction pads. Each of the three support members P includes an air suction hole V1. Each air suction hole V1 passes through each support member P in a top-to-bottom direction (i.e., thickness direction). The three support members P are configured to hold the substrate W by suction through air suction from the respective air suction holes V1. The air suction holes V1 of each of the three support members P extend to an inside of the fork FK31. The fork FK31 includes a suction path V2 formed therein. The air suction holes V1 of each of the three support members P are connected to the suction path V2.

The processing system PS may further include an exhaust pipe V3, an exhaust device V4, and at least one suction sensor V5. The processing system PS includes one suction sensor V5 as the at least one suction sensor V5. A plurality of air suction holes V1 are connected to the exhaust device V4 via the suction path V2 and the exhaust pipe V3. The exhaust device V4 includes a valve, a regulator, a vacuum pump, and the like. The exhaust device V4 suctions air from the air suction hole V1, the suction path V2, and the exhaust pipe V3 while adjusting a pressure in each of the air suction hole V1, the suction path V2, and the exhaust pipe V3. The air suction hole V1 is also connected to the suction sensor V5 via the suction path V2 and the exhaust pipe V3. The suction sensor V5 measures a pressure reflecting a suction force of the conveyance robot TR3. The suction sensor V5 measures the pressure reflecting the suction force of the conveyance robot TR3 with respect to the substrate W in a state where the substrate W is mounted on the three support members P. The suction sensor V5 measures the pressure (hereinafter, also referred to as the “suction force”) in the exhaust pipe V3 and provides notification of the measured pressure to the determiner 93 of the control device CU.

Hereinafter, each configuration of the processing system according to one exemplary embodiment will be described in detail. First, details of each configuration in the cleaning station CL will be described with reference to FIG. 1 again. The cleaning station CL is provided with the substrate mount 10, the at least one position measurer 20, the foreign matter removal device 30, the polishing device 40, and the imaging device 50. In the cleaning station CL, the at least one position measurer 20, the foreign matter removal device 30, the polishing device 40, the imaging device 50, and the substrate mount 10 are arranged in this order in an upward direction. In cleaning the three support members P, first, the conveyance robot TR3 passes the substrate W from the end effector EE31 to the substrate mount 10. Then, the conveyance robot TR3 moves the end effector EE31 to each of target regions 20a, 30a, 41a, 46a, and 50a in which functions of each of the position measurer 20, the foreign matter removal device 30, the polishing device 40, and the imaging device 50 can be exhibited.

The substrate mount 10 includes a mount surface 11. The substrate mount 10 supports the substrate W mounted on the mount surface 11. The mount surface 11 may be configured with several pads.

The processing system PS includes three position measurers 20 as the at least one position measurer 20. The three position measurers 20 measure positions and inclinations of the three support members P with respect to at least one of the foreign matter removal device 30, the polishing device 40, or the imaging device 50. In the example shown in FIG. 1, the three position measurers 20 may not be provided in a straight line. The three position measurers 20 may be provided on the same plane along a horizontal direction. Each of the three position measurers 20 includes a laser displacement meter.

The three position measurers 20 emit laser beams to a stage 32 (described later) of the foreign matter removal device 30. The laser beams are emitted in the upward direction. The three position measurers 20 measure distances from each of the three position measurers 20 to the stage 32 of the foreign matter removal device 30 by emitting the laser beams. The three position measurers 20 provide notification of each measured distance to the determiner 93 of the control device CU. Here, for example, a case where the three distances are different from each other indicates that the stage 32 is inclined. Each measured distance is an indicator of an inclination of the stage 32.

The three position measurers 20 emit the laser beams to the end effector EE31 moved to the target region 20a of the position measurers 20 by the conveyance robot TR3. The target region 20a of each position measurer 20 is a region in which a function of measuring the positions of the three support members P by each position measurer 20 can be exhibited. The target region 20a is, for example, a region to which the laser beams from the three position measurers 20 can be emitted. The target region 20a is, for example, a space above the three position measurers 20. The target region 20a includes at least the stage 32 of the foreign matter removal device 30.

The three position measurers 20 measure the inclinations of the three support members P with respect to the foreign matter removal device 30. In the example shown in FIG. 1, the inclinations of the three support members P provided on the end effector EE31 are measured by measuring an inclination of the end effector EE31. Since the three support members P are provided on the fork FK31 of the end effector EE31, the inclinations of the three support members P are the same as the inclination of the end effector EE31. The three position measurers 20 measure distances from each of the three position measurers 20 to the end effector EE31 by emitting the laser beams. The three position measurers 20 provide notification of each measured distance to the determiner 93 of the control device CU. Each measured distance is an indicator of the inclinations of the three support members P.

The three position measurers 20 measure the positions of the three support members P. As an example of measuring the positions of the three support members P, the three position measurers 20 measure positions of the three markers M provided in the end effector EE31. That is, the positions of the three support members P are measured by measuring the positions of the three markers M. Each of the three position measurers 20 emits the laser beam to each corresponding marker M and receives reflected light from each marker M. For example, intensity of the reflected light from each marker M to which the laser beams are emitted is greater than intensity of the reflected light from a region other than each marker M of the end effector EE31 to which the laser beams are emitted. The intensity of the reflected light from each marker M is stored in advance. The three position measurers 20 detect positional deviation in the horizontal direction based on the intensity of the received reflected light. For example, the laser beams are emitted directly upward from the three position measurers 20. In a case where the intensity of the reflected light of the laser beams does not correspond to the intensity of the reflected light from each marker M, the three position measurers 20 and the three markers M positionally deviate from each other in the horizontal direction. In a case where the intensity of the reflected light of the laser beams corresponds to the intensity of the reflected light from each marker M, the three position measurers 20 and the three markers M positionally match each other in the horizontal direction.

The foreign matter removal device 30 removes foreign matter attached to the at least one support member P. The foreign matter removal device 30 removes the foreign matter attached to the at least one support member P of the end effector EE31 moved to the target region 30a of the foreign matter removal device 30 by the conveyance robot TR3. The target region 30a of the foreign matter removal device 30 is a region in which a function of removing the foreign matter by the foreign matter removal device 30 can be exhibited. The foreign matter removal device 30 includes a blowing device 31 and at least one dust collection device 36. The blowing device 31 removes the foreign matter attached to the at least one support member P by air blowing.

The blowing device 31 includes the stage 32, a blowing pipe 33, and at least one blowing nozzle 34. The stage 32 is a plate-shaped member extending in the horizontal direction. For example, the stage 32 is disposed above the three position measurers 20 and the target region 30a. The stage 32 is provided at a position facing the three position measurers 20. The stage 32 includes a part of the blowing pipe 33 formed therein. For example, one end of the blowing pipe 33 is connected to a blower 35. The other end of the blowing pipe 33 is connected to the at least one blowing nozzle 34.

The blowing device 31 includes three blowing nozzles 34 corresponding to the three support members P, respectively, as the at least one blowing nozzle 34. One end of each blowing nozzle 34 protrudes downward from a lower surface of the stage 32 to a dust collection device 36a (described later). The blowing device 31 starts the blower 35 to supply air to the blowing pipe 33, thereby ejecting air from each blowing nozzle 34 and enabling air blowing toward the target region 30a. For example, in each support member P positioned at a target position in the target region 30a, each blowing nozzle 34 protrudes in a direction of the pair of arms 312 and 312 from the base end 311 of the end effector EE31 to perform the air blowing to each support member P in the direction. By moving the three support members P to the target position in the target region 30a by the conveyance robot TR3, the foreign matter attached to the three support members P is blown off by the air blowing.

The processing system PS shown in FIG. 1 includes three dust collection devices 36a, 36b, and 36c as the at least one dust collection device 36. The dust collection devices 36a, 36b, and 36c are provided to correspond to the foreign matter removal device 30, a first polisher 41 (described later) of the polishing device 40, and a second polisher 46 (described later) of the polishing device 40, respectively. The dust collection devices 36a, 36b, and 36c are arranged in this order in the upward direction. Each of the dust collection devices 36a, 36b, and 36c includes a suction port 37 and a dust collection pipe 38. The dust collection devices 36a, 36b, and 36c are configured to suction dust in the target regions 30a, 41a, and 46a through air suction from the respective suction ports 37. Some parts of each of the dust collection pipes 38 of the dust collection devices 36a, 36b, and 36c are formed in the same pipeline. Each suction port 37 is connected to the exhaust device 39 via each dust collection pipe 38. The exhaust device includes, for example, a valve, a regulator, a vacuum pump, and the like. The exhaust device 39 suctions dust from the suction ports 37 through air suction in the dust collection pipes 38 while adjusting pressures in each of the suction ports 37 and the dust collection pipes 38.

The dust collection device 36a collects the foreign matter removed by the blowing device 31. The suction port 37 of the dust collection device 36a is provided in a direction of the air blowing from each blowing nozzle 34 with respect to each blowing nozzle 34. The dust collection device 36b collects fine powder and grit generated by the first polisher 41 (described later) of the polishing device 40. The dust collection device 36c collects fine powder and grit generated by polishing in the second polisher 46 (described later) of the polishing device 40. For example, the suction ports 37 of each of the dust collection devices 36b and 36c are provided at the same position as the suction port 37 of the dust collection device 36a in the horizontal direction.

The polishing device 40 cleans the three support members P. As an example of the cleaning, the polishing device 40 polishes the three support members P. The polishing device 40 includes the first polisher 41 and the second polisher 46. The first polisher 41 is provided below the second polisher 46. The first polisher 41 polishes the three support members P of the end effector EE31 moved to the target region 41a of the first polisher 41 by the conveyance robot TR3. The target region 41a of the first polisher 41 is a region in which a function of polishing the support members P by the first polisher 41 can be exhibited. The first polisher 41 includes a stage 42 and at least one polishing member 43. The stage 42 is a plate-shaped member extending in the horizontal direction. For example, the stage 42 is disposed above the target region 41a. The stage 42 of the first polisher 41 is provided directly above the stage 32 of the foreign matter removal device 30 and is provided parallel to the stage 32. The first polisher 41 includes three polishing members 43 corresponding to the three support members P, respectively, as the at least one polishing member 43. The three support members P are physically polished by the three polishing members 43, respectively. The three polishing members 43 are provided on a lower surface of the stage 42. When the conveyance robot TR3 moves the three support members P to the target position in the horizontal direction, the three polishing members 43 are positioned directly above the three support members P. By causing the end effector EE31 to slide in the horizontal direction relative to the three polishing members 43 by the conveyance robot TR3, each of the three polishing members 43 polishes each corresponding support member P.

The second polisher 46 polishes the three support members P of the end effector EE31 moved to the target region 46a of the second polisher 46 by the conveyance robot TR3. The target region 46a of the second polisher 46 is a region in which a function of polishing the support members P by the second polisher 46 can be exhibited. The second polisher 46 includes a stage 47 and at least one polishing member 48. The stage 47 is a plate-shaped member extending in the horizontal direction. For example, the stage 47 is disposed above the target region 46a. The stage 47 of the second polisher 46 is provided directly above the stage 42 of the first polisher 41 and is provided parallel to the stage 32 of the foreign matter removal device 30. The second polisher 46 includes three polishing members 48 corresponding to the three support members P, respectively, as the at least one polishing member 48. The three support members P are physically polished by the three polishing members 48, respectively. The three polishing members 48 are provided on a lower surface of the stage 47. When the conveyance robot TR3 moves the three support members P to the target position in the horizontal direction, the three polishing members 48 are positioned directly above the three support members P. By causing the end effector EE31 to slide in the horizontal direction relative to the three polishing members 48 by the conveyance robot TR3, each of the three polishing members 48 polishes each corresponding support member P.

The grit of each of the three polishing members 48 in the second polisher 46 is smaller than the grit of each of the three polishing members 43 in the first polisher 41. Any of polishing by only the first polisher 41, polishing by only the second polisher 46, or polishing by the first polisher 41 and the second polisher 46 is selected depending on a size of a damaged region of each support member P caused by damage or wear on each support member P. The damaged region is a region including damage. The damage in the damaged region includes a dent or fluff. For example, the above selection of the polisher is made with reference to the support member P having the largest damaged region among the three support members P.

For example, in a case where the size of the damaged region is relatively large, the polishing by the first polisher 41 is selected. In polishing the three support members P via the first polisher 41, the conveyance robot TR3 moves the end effector EE31 to the target region 41a of the first polisher 41, and the three support members P are polished by causing the three support members P to slide on the three polishing members 43. Accordingly, a difference in height between the damaged region of the support member P caused by damage or wear on the support member P and a region other than the damaged region of the support member P is reduced.

For example, in a case where the size of the damaged region is relatively small, or in a case where finishing after the polishing by the first polisher 41 is performed, the polishing by the second polisher 46 is selected. In polishing the three support members P via the second polisher 46, the conveyance robot TR3 moves the end effector EE31 to the target region 46a of the second polisher 46, and the three support members P are polished by causing the three support members P to slide on the three polishing members 48. Accordingly, the difference between the damaged region and the other region in a height direction can be further reduced, and the whole support member P is smoothly finished.

The imaging device 50 acquires, as pre-cleaning images and post-cleaning images of the three support members P, images of at least one support member P before and after being cleaned by the polishing device 40. Specifically, the imaging device 50 acquires images of the at least one support member P at each time before and after the polishing by the polishing device 40 as pre-polishing images and post-polishing images of the three support members P. The pre-polishing images are examples of the pre-cleaning image. The imaging device 50 acquires images including the three support members P before polishing the three support members P by at least one of the first polisher 41 and/or the second polisher 46 of the polishing device 40 as the pre-polishing images. The post-polishing images are examples of the post-cleaning image. The imaging device 50 acquires images including the three support members P, as pre-polishing images, before the three support members P are polished by at least one of the first polishing unit 41 and/or the second polishing unit 46 of the polishing device 40.

The imaging device 50 includes a camera 51 and a stage 52. The camera 51 acquires the images of the three support members P of the end effector EE31 moved to the target region 50a of the imaging device 50 by the conveyance robot TR3. The target region 50a of the imaging device 50 is a region in which a function of acquiring the images of the support members P by the imaging device 50 can be exhibited. The target region 50a is, for example, a region in which the camera 51 of the imaging device 50 can image a target. The camera 51 images the three support members P after adjusting focus on each support member P. The camera 51 includes, for example, a CCD sensor. The stage 52 is a plate-shaped member extending in the horizontal direction. For example, the stage 52 is disposed above the target region 50a. The stage 52 of the imaging device 50 is provided directly above the stage 47 of the second polisher 46 and is provided parallel to the stage 32 of the foreign matter removal device 30. The camera 51 is provided on a lower surface of the stage 52.

Hereinafter, a configuration of the control device CU and processing in the control device CU will be described. The control device CU may include the determiner 93. The control device CU may include a controller 92 (i.e., controller circuitry). First, the controller 92 controls the conveyance robot TR3. A flow of a procedure of passing the substrate W from the end effector EE31 to the substrate mount 10 will be described. The controller 92 controls the conveyance robot TR3 to convey the substrate W to a region above the substrate mount 10 of the aligner AN in a state where the substrate W is mounted on the three support members P of the end effector EE31. Next, the controller 92 controls the exhaust device V4 to stop holding the substrate W by suction in the end effector EE31. Next, the controller 92 controls the conveyance robot TR3 to lower the end effector EE31 to a region below the mount surface 11 of the substrate mount 10. As shown in FIG. 1, by lowering the end effector EE31, the substrate W is mounted on the mount surface 11, and the end effector EE31 is separated downward from the substrate W.

Accordingly, the substrate W is passed from the end effector EE31 to the substrate mount 10. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

In a case where the substrate W is passed from the substrate mount 10 to the end effector EE31, the controller 92 controls the conveyance robot TR3 to raise the end effector EE31 upward from the region below the mount surface 11 of the substrate mount 10. Accordingly, the end effector EE31 lifts the substrate W from the mount surface 11 of the substrate mount 10 by supporting the substrate W on the three support members P. After lifting the substrate W from the mount surface 11 of the substrate mount 10, the controller 92 controls the conveyance robot TR3 to hold the substrate W by suction and convey the substrate W.

Hereinafter, a flow of processing until the control device CU cleans the three support members P will be described. First, the determiner 93 determines whether or not a state of the at least one support member P is good to determine whether or not cleaning of the three support members P is necessary. As an example of determining whether or not the state of the at least one support member P is good, the determiner 93 detects an abnormality in the suction force of the conveyance robot TR3 with respect to the substrate W. In order to detect the abnormality in the suction force of the conveyance robot TR3, air suction starts from a state where the substrate W is mounted on the three support members P and air suction via the exhaust device V4 is stopped. The three support members P hold the substrate W by suction through air suction from the respective air suction holes V1. The suction sensor V5 measures the pressure in the exhaust pipe V3 communicating with the air suction holes V1 as the suction force. The suction sensor V5 provides notification of a measured value of the measured pressure to the determiner 93 of the control device CU.

The determiner 93 determines whether or not the suction force of the conveyance robot TR3 with respect to the substrate W is abnormal based on the measured value of the pressure provided by the notification from the suction sensor V5. First, the determiner 93 detects the abnormality in the suction force of the conveyance robot TR3 by comparing the measured value of the pressure provided by the notification with a threshold value. The threshold value is set in advance. In a case where the measured value of the pressure is less than the threshold value, the determiner 93 determines that the suction force of the conveyance robot TR3 is abnormal. That is, in a case where the measured value of the pressure is less than the threshold value, the determiner 93 determines that the state of the at least one support member P is not good. The determiner 93 further detects the abnormality in the suction force of the conveyance robot TR3 by comparing a time from when the measured value of the pressure is measured to when the measured value of the pressure reaches the threshold value with a set time. The set time is set in advance. In a case where the time from when the measured value of the pressure is measured to when the measured value of the pressure reaches the threshold value is longer than the set time, the determiner 93 determines that the suction force of the conveyance robot TR3 is abnormal. That is, in a case where the time from when the measured value of the pressure is measured to when the measured value of the pressure reaches the threshold value is longer than the set time, the determiner 93 determines that the state of the at least one support member P is not good. Here, in a case where states of the three support members P supporting the substrate W are good and the suction force is normal, the measured value of the pressure is greater than or equal to the threshold value, and the time from when the measured value of the pressure is measured to when the measured value of the pressure reaches the threshold value is shorter than the set time.

However, in a case where the end effector EE31 including the at least one support member P supporting the substrate W is stained for any reason, it is likely that the substrate W is not sufficiently held by suction on the at least one support member P. In particular, since the at least one support member P is exposed on a surface of the end effector EE31, it is highly likely that the at least one support member P is stained compared to the suction path V2 and the exhaust pipe V3. In this case, the substrate W is easily separated from the at least one support member P because of a low suction force. Alternatively, a long time is required until the substrate W is appropriately held by suction on the at least one support member P. Thus, in any one of a case where the measured value of the pressure is less than the threshold value, or a case where the time from when the measured value of the pressure is measured to when the measured value of the pressure reaches the threshold value is longer than the set time, it is determined that the suction force of the conveyance robot TR3 with respect to the substrate W is abnormal.

In one embodiment, in a case where the determiner 93 determines that the suction force of the conveyance robot TR3 with respect to the substrate W is abnormal, the controller 92 controls the conveyance robot TR3 to move the end effector EE31 to the cleaning station CL. The controller 92 controls the cleaning station CL to clean the three support members P on the end effector EE31. In the cleaning station CL, for example, the air blowing, the polishing, or both of the air blowing and the polishing are performed on the at least one support member P.

In one embodiment, the controller 92 controls the conveyance robot TR3 and the position measurers 20 to adjust the positions and the inclinations of the three support members P with respect to the foreign matter removal device 30. The controller 92 controls the conveyance robot TR3 to move the end effector EE31 to the target region 20a corresponding to the position measurers 20. The controller 92 measures the distances to the stage 32 of the foreign matter removal device 30 and the distances to the three support members P of the end effector EE31 by the three position measurers 20. The controller 92 acquires the inclination of the stage 32 of the foreign matter removal device 30 and the inclinations of the three support members P of the end effector EE31 measured by the three position measurers 20. The controller 92 controls the conveyance robot TR3 to align the inclinations of the three support members P of the end effector EE31 with the inclination of the stage 32 of the foreign matter removal device 30.

Specifically, the controller 92 acquires the distances from each of the three position measurers 20 to the stage 32 of the foreign matter removal device 30. The controller 92 acquires the distances from each of the three position measurers 20 to the end effector EE31. The controller 92 controls movement of the conveyance robot TR3 to match a ratio of three distances from the three position measurers 20 to the end effector EE31 to a ratio of three distances from the three position measurers 20 to the stage 32 of the foreign matter removal device 30. Accordingly, the inclination of the end effector EE31 is adjusted, and the inclinations of the three support members P provided on the end effector EE31 are adjusted.

The controller 92 measures the positions of the three support members P of the end effector EE31 via the three position measurers 20. As an example of measuring the positions of the three support members P, the controller 92 controls the three position measurers 20 to measure the positions of the three markers M provided in the end effector EE31. As described above, the controller 92 controls the conveyance robot TR3 to move the positions of the three markers M of the end effector EE31 to be directly above the three position measurers 20 based on the intensity of the reflected light from the markers M. Accordingly, the controller 92 can control the conveyance robot TR3 to move the three support members P to the target position.

Here, each of the stage 42 of the first polisher 41, the stage 47 of the second polisher 46, and the stage 52 of the imaging device 50 is provided directly above the stage 32 of the foreign matter removal device 30 and is provided parallel to the stage 32. Thus, as described above, the controller 92 can also control the inclinations of the three support members P with respect to the stage 42 of the first polisher 41, the stage 47 of the second polisher 46, and the stage 52 of the imaging device 50 by controlling the inclinations of the three support members P.

The controller 92 stores a movement amount of the end effector EE31 in the horizontal direction when the conveyance robot TR3 moves the end effector EE31 to match the positions of the three position measurers 20 to the positions of the three markers M in the target region 20a. For example, the controller 92 moves the end effector EE31 by the movement amount with respect to the target region 30a of the foreign matter removal device 30 via the conveyance robot TR3. Accordingly, the conveyance robot TR3 can move the three support members P of the end effector EE31 to a position at which the removal of the foreign matter in the foreign matter removal device 30 can be executed. In addition, for example, the controller 92 moves the end effector EE31 by the movement amount with respect to the target region 41a and the target region 46a of the polishing device 40 by the conveyance robot TR3. Accordingly, the conveyance robot TR3 can move the three support members P of the end effector EE31 to a position at which the polishing in the polishing device 40 can be executed. Furthermore, for example, the controller 92 moves the end effector EE31 by the movement amount with respect to the target region 50a of the imaging device 50 by the conveyance robot TR3. Accordingly, the conveyance robot TR3 can move the three support members P of the end effector EE31 to a position at which the imaging in the imaging device 50 can be executed. The positions of the three support members P in the horizontal direction will be referred to as the target position. The controller 92 can move the end effector EE31 to the target position with respect to the foreign matter removal device 30, the polishing device 40, and the imaging device 50 in the horizontal direction by the conveyance robot TR3.

In one embodiment, the control device CU controls the conveyance robot TR3 and the foreign matter removal device 30 to remove the foreign matter attached to the three support members P. The controller 92 controls the conveyance robot TR3 to move the end effector EE31 to the target region 30a corresponding to the foreign matter removal device 30. The controller 92 starts the dust collection device 36a and then performs the air blowing to the three support members P by the blowing device 31.

In one embodiment, the controller 92 controls the conveyance robot TR3 and the dust collection devices 36b and 36c to polish the three support members P. Based on a polishing condition that is a condition when the three support members P are polished in the polishing device 40, the controller 92 controls the conveyance robot TR3 in accordance with the polishing condition. The polishing condition is set by the determiner 93. The controller 92 controls the conveyance robot TR3 to move the end effector EE31 to the target region 41a corresponding to the first polisher 41 of the polishing device 40. In the target region 41a, the controller 92 controls the conveyance robot TR3 to cause the three support members P to slide on the three polishing members 43 so that each of the three polishing members 43 polishes each of the three support members P. The controller 92 controls the conveyance robot TR3 to bring at least a part of each of the three support members P into contact with each of the three polishing members 43 in the top-to-bottom direction. The controller 92 controls the conveyance robot TR3 to move the end effector EE31 in the horizontal direction while at least a part of each of the three support members P is in contact with each of the three polishing members 43. Here, the controller 92 controls the dust collection device 36b to collect the fine powder and the grit generated by the polishing.

In one embodiment, for example, the controller 92 controls the conveyance robot TR3 to move the end effector EE31 to the target region 46a corresponding to the second polisher 46 of the polishing device 40. In the target region 46a, the controller 92 controls the conveyance robot TR3 to cause the three support members P to slide on the three polishing members 48 so that each of the three polishing members 48 polishes each of the three support members P. The controller 92 controls the conveyance robot TR3 to bring at least a part of each of the three support members P into contact with each of the three polishing members 48 in the top-to-bottom direction. The controller 92 controls the conveyance robot TR3 to move the end effector EE31 in the horizontal direction while at least a part of each of the three support members P is in contact with each of the three polishing members 48. Here, the controller 92 controls the dust collection device 36c to collect the fine powder and the grit generated by the polishing.

In one embodiment, the controller 92 controls the conveyance robot TR3 and the imaging device 50 to acquire the images of the three support members P at each time before and after the polishing as the pre-polishing images and the post-polishing images of the three support members P. The controller 92 controls the conveyance robot TR3 to move the end effector EE31 to the target region 50a corresponding to the imaging device 50. The controller 92 controls the conveyance robot TR3 to position each support member P directly below the camera 51. The controller 92 controls the imaging device 50 to image each of the three support members P before the polishing by the polishing device 40. The controller 92 controls the imaging device 50 to image each of the three support members P after the polishing by the polishing device 40.

In one embodiment, the determiner 93 detects at least one damaged region of the three support members P in the pre-polishing images of the three support members P in which the abnormality in the suction force of the conveyance robot TR3 with respect to the substrate W is detected. The determiner 93 determines whether or not at least one damaged region is present in at least one target region in the post-polishing images at the same position as the at least one damaged region in the pre-polishing images. A case where the at least one damaged region is detected in the at least one target region in the post-polishing images by the determiner 93 will be described. The determiner 93 calculates a difference between the size of the at least one damaged region in the pre-polishing images and the size of the damaged region in the at least one target region in the post-polishing images. The size of the damaged region may be an area of the damaged region, a length of the damaged region in a depth direction, or a width of the damaged region. The size of the damaged region may be the area of the damaged region per unit area, the length of the damaged region in the depth direction per unit length, or the width of the damaged region per unit width.

In a case where a plurality of damaged regions are detected in the at least one target region in the post-polishing images, a sum of sizes of the plurality of damaged regions is calculated as the size of the damaged region in the at least one target region in the post-polishing images. In a state where the damaged region present before the polishing is not detected anymore after the polishing by the polishing device 40, the size of the damaged region in the post-polishing images is set to zero. The determiner 93 detects an abnormality in the states of the support members P in which the damaged region is detected before the polishing, by comparing the difference between the size of the at least one damaged region in the pre-polishing images and the size of the damaged region in the at least one target region in the post-polishing images with a set difference value. By comparing the difference with the set difference value, the determiner 93 determines whether or not the states of the support members P in which the damaged region is detected before the polishing are abnormal even after the polishing. The set difference value is set in advance. In a case where the abnormality in the state of the at least one support member P among the three support members P is detected, the determiner 93 determines that the state of the support member P is not good.

### [Cleaning Method]

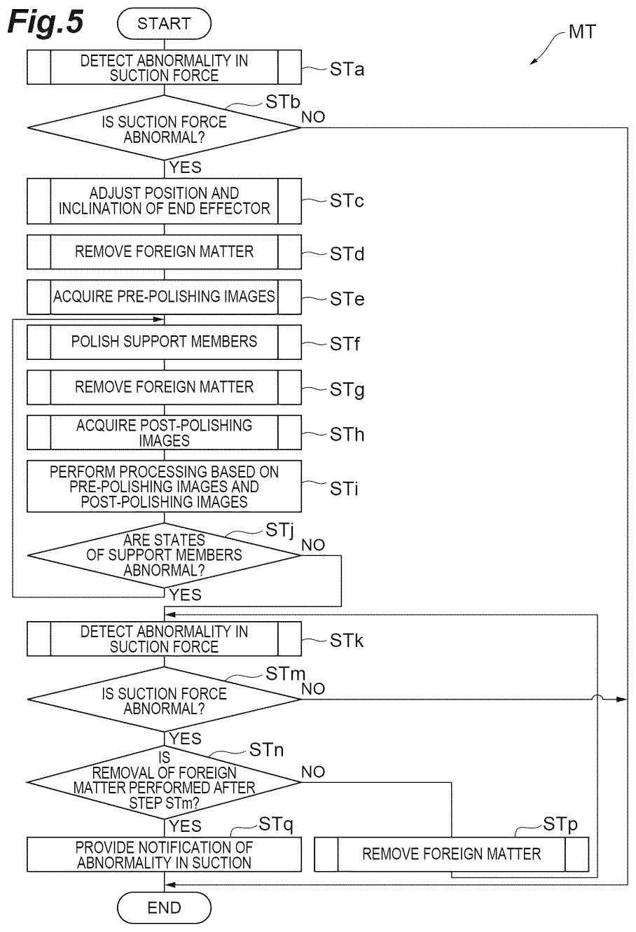

Next, a cleaning method performed in the processing system according to one exemplary embodiment will be described with reference to FIG. 5. FIG. 5 is a flowchart of the cleaning method by the processing system according to one exemplary embodiment. Hereinafter, a cleaning method MT (hereinafter, referred to as the “method MT”) shown in FIG. 5 in a case where, for example, the processing system PS is used will be described. In addition, control of each configuration and each part of the processing system PS by the control device CU in the method MT will be described. The method MT may be performed using a processing system other than the processing system PS.

In the method MT, whether or not the suction force of the conveyance robot TR3 with respect to the substrate W is abnormal is determined, and in a case where the suction force is abnormal, the removal of the foreign matter by the foreign matter removal device 30 and the polishing by the polishing device 40 are performed. Whether or not the support members P are abnormal is determined based on the pre-polishing images and the post-polishing images acquired by the imaging device 50 before and after the polishing by the polishing device 40.

The method MT includes step STa. In step STa, the suction sensor V5 measures the pressure reflecting the suction force of the conveyance robot TR3 with respect to the substrate W and detects whether or not the abnormality in the suction force is present based on the measured pressure.

In the method MT, next, step STb is performed. In step STb, the determiner 93 determines whether or not the suction force of the conveyance robot TR3 is abnormal. In a case where the abnormality in the suction force of the conveyance robot TR3 is not detected in step STa, it is determined that the suction force of the conveyance robot TR3 is not abnormal, and the method MT is finished. Meanwhile, in a case where the abnormality in the suction force of the conveyance robot TR3 is detected in step STa, it is determined that the suction force of the conveyance robot TR3 is abnormal, and processing proceeds to step STc.

In step STc, the position and the inclination of the end effector EE31 with respect to the foreign matter removal device 30, the polishing device 40, and the imaging device 50 of the cleaning station CL are adjusted by the three position measurers 20 and the conveyance robot TR3.

In the method MT, next, step STd is performed. In step STd, the foreign matter attached to the three support members P is removed by the foreign matter removal device 30 and the conveyance robot TR3. Here, the foreign matter includes a matter attached to the three support members P before the polishing in the polishing device 40.

In the method MT, next, step STe is performed. In step STe, the image of the three support members P before the polishing by the polishing device 40 is acquired by the imaging device 50 and the conveyance robot TR3.

In the method MT, next, step STf is performed. In step STf, the three support members P are polished by the polishing device 40 and the conveyance robot TR3. In step STf, the determiner 93 sets the polishing condition for polishing the three support members P in the polishing device 40, and the controller 92 controls the conveyance robot TR3 in accordance with the polishing condition.

In the method MT, next, step STg is performed. In step STg, the foreign matter attached to the three support members P is removed by the foreign matter removal device 30 and the conveyance robot TR3. Here, the foreign matter is a matter attached to the three support members P after the polishing in the polishing device 40 and includes the fine powder and the grit.

In the method MT, next, step STh is performed. In step STh, the image of the three support members P after the polishing by the polishing device 40 is acquired by the imaging device 50 and the conveyance robot TR3.

In the method MT, next, step STi is performed. In step STi, the abnormality in the states of the three support members P is detected based on the pre-polishing images acquired in step STe and the post-polishing images acquired in step STh.

In the method MT, next, step STj is performed. In step STj, the determiner 93 determines whether or not the states of the three support members P are abnormal. In a case where the abnormality in the states of the three support members P is not detected in step STi, it is determined that the states of the three support members P are not abnormal, and the processing proceeds to step STK. Meanwhile, in a case where the abnormality in the states of the three support members P is detected in step STi, it is determined that the states of the three support members P are abnormal, the processing returns to step STf, and the processing from step STf is performed again.

In step STK, the suction sensor V5 measures the pressure reflecting the suction force of the conveyance robot TR3 with respect to the substrate W and detects whether or not the abnormality in the suction force is present based on the measured pressure.

In the method MT, next, step STm is performed. In step STm, the determiner 93 determines whether or not the suction force of the conveyance robot TR3 is abnormal. In a case where the abnormality in the suction force of the conveyance robot TR3 is not detected in step STK, it is determined that the suction force of the conveyance robot TR3 is not abnormal, and the method MT is finished. Meanwhile, in a case where the abnormality in the suction force of the conveyance robot TR3 is detected in step STK, it is determined that the suction force of the conveyance robot TR3 is abnormal, and the processing proceeds to step STn.

In step STn, the determiner 93 determines whether or not the removal of the foreign matter is further performed by the foreign matter removal device 30 and the conveyance robot TR3 after step STm. In a case where it is determined that the removal of the foreign matter is not further performed by the foreign matter removal device 30 and the conveyance robot TR3 after step STm, the processing proceeds to step STp. Meanwhile, in a case where it is determined that the removal of the foreign matter is performed after step STm, the processing proceeds to step STq.

In step STp, the foreign matter attached to the three support members P is removed by the foreign matter removal device 30 and the conveyance robot TR3. Here, the foreign matter is a matter attached to the three support members P after the polishing in the polishing device 40 and is a matter attached after step STg. The processing returns to step STk, and the processing from step STk is performed again.

In step STq, an alert is issued for the suction force of the conveyance robot TR3. The alert includes notification of the abnormality in the suction force of the conveyance robot TR3. The controller 92 issues the alert by audio notification using a buzzer (not shown), screen display on a display, and the like. In a case where it is determined that the suction force is not abnormal in step STb and step STm, or in a case where the alert is issued in step STq, the method MT is finished.

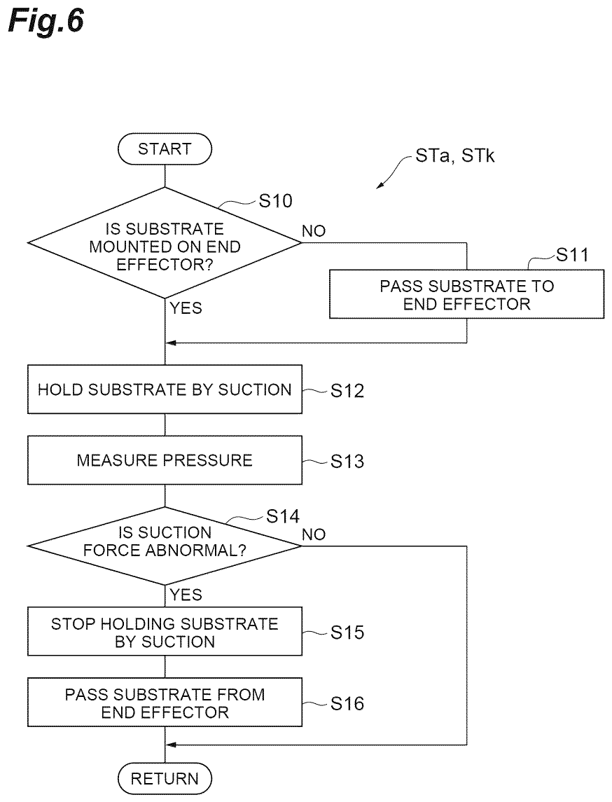

Next, details of the cleaning method performed in the processing system according to one exemplary embodiment will be described with reference to FIG. 6. FIG. 6 is a flowchart of a suction force abnormality detection method by the processing system according to one exemplary embodiment. Hereinafter, details of step STa and step STk in the method MT in a case where, for example, the processing system PS is used will be described with reference to FIG. 6. In step STa and step STk, the pressure reflecting the suction force of the conveyance robot TR3 with respect to the substrate W is measured, and the abnormality in the suction force is detected based on the measured pressure.

Step STa and step STk include step S10. In step S10, the determiner 93 determines whether or not the substrate W is mounted on the end effector EE31. In step S10, for example, the controller 92 controls the camera CM provided in the end effector EE31 to image the three support members P on the end effector EE31. The camera CM provides notification of the captured image to the determiner 93. The determiner 93 determines whether or not the substrate W is mounted on the three support members P in the image provided by the notification. In a case where the substrate W is not included in the image, it is determined that the substrate W is not mounted on the end effector EE31, and processing proceeds to step S11. Meanwhile, in a case where the substrate W is included in the image, it is determined that the substrate W is mounted on the end effector EE31, and the processing proceeds to step S12.

In step S11, the substrate W is passed to the end effector EE31 by the conveyance robot TR3. The conveyance robot TR3 raises the end effector EE31 upward from the region below the mount surface 11 of the substrate mount 10. Accordingly, the end effector EE31 lifts the substrate W from the mount surface 11 of the substrate mount 10 by supporting the substrate W on the three support members P. Thus, the substrate W is passed from the substrate mount 10 to the end effector EE31. The processing after step S11 proceeds to step S12.

In step S12, the substrate W is held by suction. The exhaust device V4 suctions air in each air suction hole V1, each suction path V2, and the exhaust pipe V3. The substrate W is held by suction on the three support members P through air suction from each air suction hole V1 provided in the three support members P.

In step STa and step STk, next, step S13 is performed. In step S13, the suction sensor V5 measures the pressure reflecting the suction force of the conveyance robot TR3. The suction sensor V5 measures the pressure in the exhaust pipe V3 for a set time after the exhaust device V4 starts suctioning air in each air suction hole V1, each suction path V2, and the exhaust pipe V3. The suction sensor V5 provides notification of the measured pressure to the determiner 93.

In step STa and step STK, next, step S14 is performed. In step S14, whether or not the suction force of the conveyance robot TR3 is abnormal is determined. In step S14, first, the determiner 93 detects the abnormality in the suction force of the conveyance robot TR3 by comparing the measured value of the pressure provided by the notification in step S13 with the threshold value. In a case where the measured value of the pressure is less than the threshold value, the determiner 93 determines that the suction force of the conveyance robot TR3 is abnormal. The determiner 93 further detects the abnormality in the suction force of the conveyance robot TR3 by comparing the time from when the measured value of the pressure is measured to when the measured value of the pressure reaches the threshold value with the set time. In a case where the time from when the measured value of the pressure is measured to when the measured value of the pressure reaches the threshold value is longer than the set time, the determiner 93 determines that the suction force of the conveyance robot TR3 is abnormal. In a case where it is determined that the suction force of the conveyance robot TR3 is abnormal in any of the above two determinations, the processing proceeds to step S15. Meanwhile, in a case where it is determined that the suction force of the conveyance robot TR3 is not abnormal in both of the above two determinations, step STa and step STk are finished.

In a case where it is determined that the suction force of the conveyance robot TR3 is abnormal, next, the step S15 is performed in step STa and step STK. In step S15, the holding of the substrate W by suction by the end effector EE31 is stopped. For example, when the end effector EE31 is not positioned in the region above the substrate mount 10, the conveyance robot TR3 conveys the substrate W to the region above the substrate mount 10 in a state where the substrate W is mounted on the three support members P. When the end effector EE31 on which the substrate W is mounted is positioned above the substrate mount 10, suctioning of air in the air suction holes V1, the suction path V2, and the exhaust pipe V3 by the exhaust device V4 is stopped. Accordingly, holding by suction between the substrate W and the three support members P is stopped.

In step STa and step STk, next, step S16 is performed. In step S16, the substrate W is passed from the end effector EE31 to the substrate mount 10 by the conveyance robot TR3. The conveyance robot TR3 that has reached the region above the substrate mount 10 lowers the end effector EE31 to the region below the mount surface 11 of the substrate mount 10. By lowering the end effector EE31, the substrate W is mounted on the mount surface 11, and the end effector EE31 is separated downward from the substrate W. Accordingly, the substrate W is passed from the end effector EE31 to the substrate mount 10. In a case where the substrate W is passed from the end effector EE31 to the substrate mount 10 in step S16, step STa and step STk as the suction force abnormality detection method shown in FIG. 6 are finished.

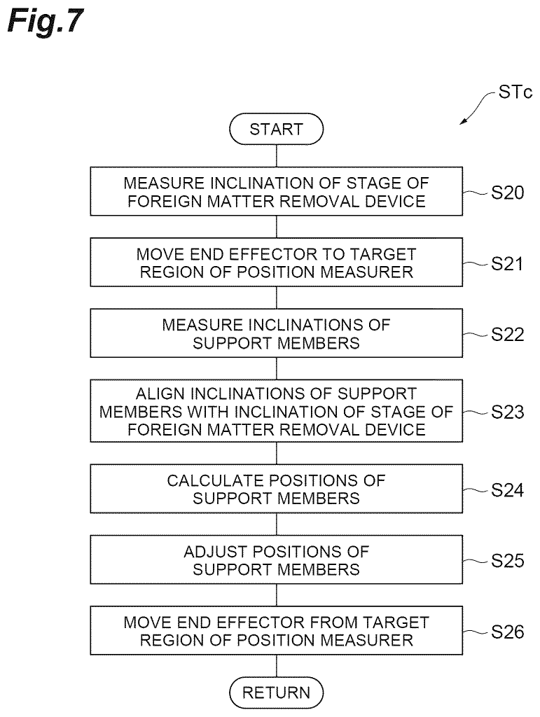

Next, details of the cleaning method performed in the processing system according to one exemplary embodiment will be described with reference to FIG. 7. FIG. 7 is a flowchart of a position adjustment method of the end effector by the processing system according to one exemplary embodiment. Hereinafter, details of step STc in the method MT in a case where, for example, the processing system PS is used will be described with reference to FIG. 7. In step STc, the position and the inclination of the end effector EE31 with respect to the foreign matter removal device 30, the polishing device 40, and the imaging device 50 are adjusted.

Step STc includes step S20. In step S20, the three position measurers 20 emit the laser beams to the stage 32 of the foreign matter removal device 30. The three position measurers 20 measure each distance from each of the three position measurers 20 to the stage 32 of the foreign matter removal device 30 by emitting the laser beams. The three position measurers 20 provide notification of each measured distance to the determiner 93. The determiner 93 uses each distance from each of the three position measurers 20 to the stage 32 of the foreign matter removal device 30 as the indicator of the inclination of the stage 32.

In step STc, next, step S21 is performed. In step S21, the conveyance robot TR3 moves the end effector EE31 to the target region 20a of the three position measurers 20. The conveyance robot TR3 moves the end effector EE31 to the space above the position measurers 20 to position the three support members P of the end effector EE31 in the target region 20a.

In step STc, next, step S22 is performed. In step S22, the three position measurers 20 emit the laser beams to the end effector EE31. The three position measurers 20 measure each distance from each of the three position measurers 20 to the end effector EE31 by emitting the laser beams. The three position measurers 20 provide notification of each measured distance to the determiner 93. The determiner 93 uses each distance from each of the three position measurers 20 to the end effector EE31 as the indicator of the inclinations of the three support members P.

In step STc, next, step S23 is performed. In step S23, the inclination of the end effector EE31 is adjusted by the conveyance robot TR3 to match the inclination of the stage 32 of the foreign matter removal device 30. The stage 42 and the stage 47 of the polishing device 40 and the stage 52 of the imaging device 50 are parallel to the stage 32 of the foreign matter removal device 30. Thus, the inclination of the end effector EE31 adjusted to match the inclination of the stage 32 of the foreign matter removal device 30 in step S23 matches an inclination of the stage 42 and an inclination of the stage 47 of the polishing device 40 and the stage 52 of the imaging device 50. That is, step STc may not be performed before steps STe, STf, STg, STh, and STp shown in FIG. 5.

In step STc, next, step S24 is performed. In step S24, the positions of the three support members P are measured by the three position measurers 20. As an example of measuring the positions of the three support members P, the three position measurers 20 measure the positions of the three markers M. Each of the three position measurers 20 emits the laser beam to each corresponding marker M and receives the reflected light. Each of the three position measurers 20 measures positional deviation between each of the three position measurers 20 and each marker M based on the intensity of the reflected light.

In step STc, next, step S25 is performed. In step S25, the positions of the three support members P are adjusted by the conveyance robot TR3. The conveyance robot TR3 moves the end effector EE31 to cause the laser beams emitted directly upward from the three position measurers 20 to hit the three markers M of the end effector EE31. That is, the controller 92 moves the end effector EE31 by the conveyance robot TR3 so that the intensity of the received reflected light from the end effector EE31 matches the intensity of the reflected light from the markers M. Accordingly, the positions of the three position measurers 20 and the three markers M match each other, and the three support members P are positioned at the target position.

In step STc, next, step S26 is performed. In step S26, the conveyance robot TR3 moves the end effector EE31 from the target region 20a of the three position measurers 20 to another region. For example, the conveyance robot TR3 moves the end effector EE31 upward to proceed to next step STd. In a case where the end effector EE31 is moved from the position measured by the three position measurers 20 in step S26, step STc as the position adjustment method shown in FIG. 7 is finished.

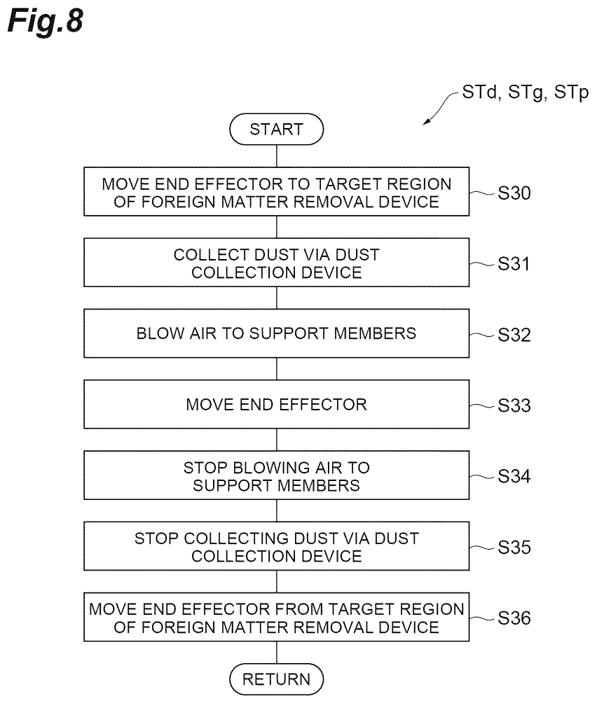

Next, details of the cleaning method performed in the processing system according to one exemplary embodiment will be described with reference to FIG. 8. FIG. 8 is a flowchart of foreign matter removal method by the processing system according to one exemplary embodiment. Hereinafter, details of steps STd, STg, and STp in the method MT in a case where, for example, the processing system PS is used will be described with reference to FIG. 8. In steps STd, STg, and STp, the foreign matter attached to the three support members P is removed.

Steps STd, STg, and STp include step S30. In step S30, the conveyance robot TR3 moves the end effector EE31 to the target region 30a of the foreign matter removal device 30. The conveyance robot TR3 moves the end effector EE31 to a space below the blowing device 31 of the foreign matter removal device 30 to position the three support members P of the end effector EE31 in the target region 30a. The conveyance robot TR3 moves the end effector EE31 to position the three support members P between the blowing nozzles 34 of the blowing device 31 and the suction port 37 of the dust collection device 36a. In a case where the end effector EE31 is moved to a region in which the target region 20a and the target region 30a overlap with each other in step STc, step S30 may not be performed in step STd. In this case, step S26 may not be performed in step STc, or step STc as the position adjustment method may be finished in step S25.

In steps STd, STg, and STp, next, step S31 is performed. In step S31, the dust collection device 36a suctions dust in the target region 30a. The control device CU starts the exhaust device 39 of the dust collection device 36a in advance to suction dust in the target region 30a before step S22. The exhaust device 39 suctions dust from the suction ports 37 through air suction in the dust collection pipes 38.

In steps STd, STg, and STp, next, step S32 is performed. In step S32, the foreign matter removal device 30 removes the foreign matter attached to the three support members P. The controller 92 starts the blower 35 of the blowing device 31 and controls the foreign matter removal device 30 to supply air to the blowing nozzles 34 via the blowing pipe 33. Accordingly, the air blowing is performed on the three support members P.

In steps STd, STg, and STp, next, step S33 is performed. In step S33, the end effector EE31 is moved in the target region 30a of the foreign matter removal device 30 by the conveyance robot TR3. The controller 92 causes the air blowing to hit the three support members P from various positions to easily remove the foreign matter attached to the three support members P. The controller 92 controls the conveyance robot TR3 to move the end effector EE31 forward, rearward, upward, downward, leftward, and rightward with respect to the blowing nozzles 34. The controller 92 continues the air blowing to the three support members P during movement and after movement of the three support members P.

In steps STd, STg, and STp, next, step S34 is performed. In step S34, the removal of the foreign matter attached to the three support members P by the foreign matter removal device 30 is finished. The controller 92 stops the blower 35 of the blowing device 31 and controls the foreign matter removal device 30 not to supply air to the blowing nozzles 34 via the blowing pipe 33. Accordingly, the air blowing to the three support members P is finished.

In steps STd, STg, and STp, next, step S35 is performed. In step S35, the dust collection in the target region 30a by the dust collection device 36a is stopped. The controller 92 stops air suction by the exhaust device 39 of the dust collection device 36a and stops air suction in the dust collection pipes 38. Accordingly, the processing of suctioning dust from the suction ports 37 is finished.

In steps STd, STg, and STp, next, step S36 is performed. In step S36, the conveyance robot TR3 moves the end effector EE31 from the target region 30a of the foreign matter removal device 30 to another region. For example, the conveyance robot TR3 retracts the end effector EE31 to proceed to the next step. In a case where the end effector EE31 is moved from the target region 30a in step S36, steps STd, STg, and STp as the foreign matter removal method shown in FIG. 8 are finished.

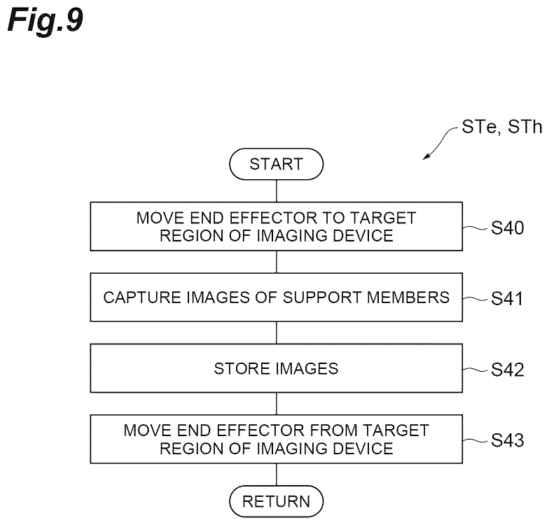

Next, details of the cleaning method performed in the processing system according to one exemplary embodiment will be described with reference to FIG. 9. FIG. 9 is a flowchart of an image acquisition method by the processing system according to one exemplary embodiment. Hereinafter, details of step STe in the method MT in a case where, for example, the processing system PS is used will be described with reference to FIG. 9. In step STe, the pre-polishing images of each of the three support members P are acquired before the polishing by the polishing device 40.

Step STe includes step S40. In step S40, the conveyance robot TR3 moves the end effector EE31 to the target region 50a of the imaging device 50. The conveyance robot TR3 moves the end effector EE31 to a space below the imaging device 50 to position one support member P among the three support members P of the end effector EE31 in the target region 50a.

In step STe, next, step S41 is performed. In step S41, the imaging device 50 acquires the pre-polishing images of the three support members P. The controller 92 controls the imaging device 50 to image each support member P by focusing on each support member P in the camera 51. Accordingly, the imaging device 50 acquires the pre-polishing images including the three support members P.

In step STe, next, step S42 is performed. In step S42, the controller 92 stores the acquired pre-polishing images. The control device CU stores a date and time at which the pre-polishing images are acquired, together with the pre-polishing images.

In step STe, next, step S43 is performed. In step S43, the conveyance robot TR3 moves the end effector EE31 from the target region 50a of the imaging device 50 to another region. For example, the conveyance robot TR3 retracts the end effector EE31 to proceed to next step STf. In a case where the end effector EE31 is moved from the target region 50a of the imaging device 50 in step S43, step STe as the image acquisition method shown in FIG. 9 is finished.

The same applies to details of step STh in the method MT. In step STh, after the polishing by the polishing device 40, the post-polishing images of each of the three support members P are acquired. Step STh is performed by replacing above step STe and the pre-polishing images with step STh and the post-polishing images, respectively. In step S43, for example, the conveyance robot TR3 retracts the end effector EE31 to proceed to next step STf or step STK.

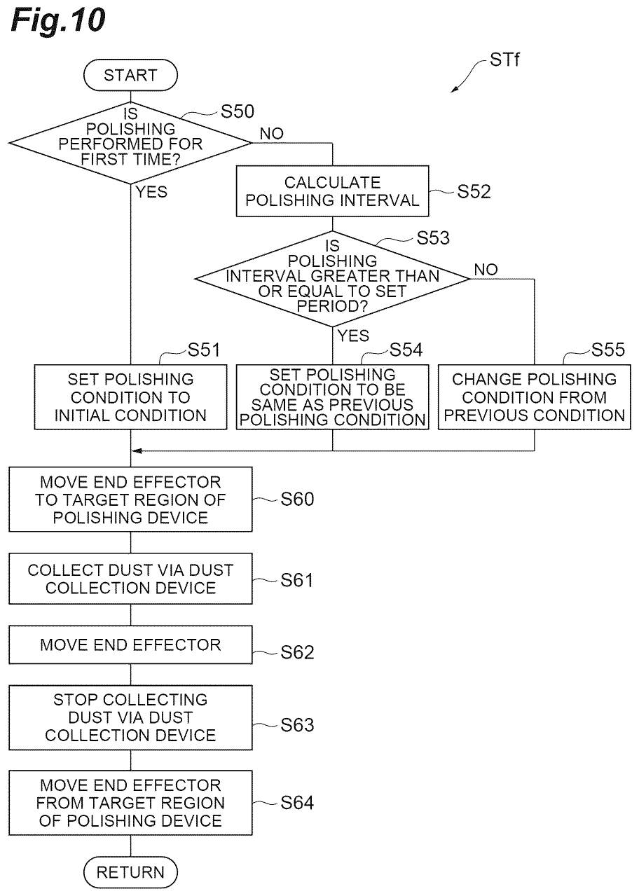

Next, details of the cleaning method performed in the processing system according to one exemplary embodiment will be described with reference to FIG. 10. FIG. 10 is a flowchart of a polishing method of the support member by the processing system according to one exemplary embodiment. Hereinafter, details of step STf in the method MT in a case where, for example, the processing system PS is used will be described with reference to FIG. 10. In step STf, the polishing condition in the polishing device 40 is set, and each of the three support members P is polished in the polishing device 40. The polishing method of the support members P includes, for example, a setting step of the polishing condition including steps S50 to S55 and a polishing step including steps S60 to S64.

Step STf includes step S50. In step S50, the determiner 93 determines whether or not the polishing performed in subsequent step STf is the polishing performed for the first time for the three support members P. For example, the determiner 93 determines whether or not the polishing is performed by determining whether or not the pre-polishing images are acquired in step STe. In a case where the pre-polishing images are not acquired in step STe, it is determined that the polishing performed in subsequent step STf is the polishing performed for the first time for the three support members P, and processing proceeds to step S51. In a case where the pre-polishing images are acquired in step STe, it is determined that the polishing performed in subsequent step STf is not the polishing performed for the first time for the three support members P, and the processing proceeds to step S52.

In step S51, the determiner 93 sets the polishing condition to an initial condition. The initial condition is set in advance. The determiner 93 sets a selection condition, a polishing time condition, a polishing movement condition, and the like of the polisher included in the polishing condition to the initial condition. The selection condition of the polisher is a condition as to whether or not to polish the three support members P in any of the first polisher 41, the second polisher 46, or both of the first polisher 41 and the second polisher 46. For example, in the initial condition, the polishing of the three support members P is set to be executed in only the first polisher 41. For example, in a case where fine polishing is necessary, performing the polishing in the second polisher 46 may be set as the initial condition. For example, in a case where polishing for finishing is necessary after the polishing in the first polisher 41, performing the polishing in both of the first polisher 41 and the second polisher 46 may be set as the initial condition. The polishing time condition is a time for positioning the three support members P in the target region 40a of the polishing device 40. The polishing movement condition is a condition related to movement ranges of the three support members P with respect to the polishing members 43 and the polishing members 48 of the polishing device 40. The polishing movement condition includes a condition related to the number of times the three support members P slide on the polishing members 43 and the polishing members 48 of the polishing device 40 in the horizontal direction, and a distance by which the three support members P are brought close to the polishing members 43 and the polishing members 48 of the polishing device 40.

In step S52, the determiner 93 calculates a polishing interval that is a period from when the three support members P are previously polished to when step S52 is performed. For example, as a time when the three support members P are previously polished, the determiner 93 acquires the date and time stored together with the post-polishing images in step S42 in step STh. The determination unit 93, for example, acquires the stored date and time as the date and time when it was obtained. The determiner 93 calculates the polishing interval based on the stored date and time and the acquired date and time.

In step STf, next, step S53 is performed. In step S53, the determiner 93 determines whether or not the calculated polishing interval is greater than or equal to a set period. The set period is set in advance. In a case where it is determined that the polishing interval is greater than or equal to the set period, the processing proceeds to step S54. In a case where it is determined that the polishing interval is not greater than or equal to the set period, the processing proceeds to step S55.

In a case where it is determined that the polishing interval is greater than or equal to the set period in step S53, next, step S54 is performed in step STf. In step S54, the polishing condition is set to be the same as the previous polishing condition. By setting the polishing condition to be the same as the previous polishing condition, the determiner 93 can adopt a condition in which the three support members P are effectively polished, such as a condition that the polishing interval is greater than or equal to the set period.

In a case where it is determined that the polishing interval is not greater than or equal to the set period in step S53, next, step S55 is performed in step STf. In step S55, the polishing condition is changed from the previous polishing condition. For example, in a case where the polishing interval is less than the set period, the determiner 93 determines that effective polishing is not performed in the previous polishing, and sets a strict polishing condition to polish the three support members P more. Setting the strict polishing condition may include, for example, setting a long polishing time as the polishing time condition. Setting the strict polishing condition may include, for example, increasing the number of times sliding is performed on the polishing members 43 and the polishing members 48 of the polishing device 40 in the horizontal direction per unit time as the polishing movement condition. Setting the strict polishing condition may include, for example, reducing a distance by which the three support members P are brought close to the polishing members 43 and the polishing members 48 of the polishing device 40 as the polishing movement condition. By changing the polishing condition to be strict from the previous polishing condition, the determiner 93 can reduce achievement of the same result as the previous polishing condition such that the polishing interval is less than the set period.

In step STf, after the polishing condition is set in any of steps S51, S54, and S55, a polishing step including steps S60 to S64 is performed. In step STf, next, step S60 is performed. In step S60, the conveyance robot TR3 moves the end effector EE31 to the target region 41a of the first polisher 41 of the polishing device 40. The conveyance robot TR3 moves the end effector EE31 to a space below the stage 42 of the first polisher 41 to position the three support members P of the end effector EE31 in the target region 41a. The conveyance robot TR3 moves the end effector EE31 to bring the three support members P into contact with the lower surfaces of the three polishing members 43 based on the polishing movement condition of the polishing condition.

In step STf, next, step S61 is performed. In step S61, the dust collection device 36b suctions dust in the target region 41a. The controller 92 starts the exhaust device 39 of the dust collection device 36b in advance to suction dust in the target region 41a before step S62. The exhaust device 39 suctions dust from the suction ports 37 through air suction in the dust collection pipes 38.

In step STf, next, step S62 is performed. In step S62, the conveyance robot TR3 causes the three support members P on the end effector EE31 to slide on the three polishing members 43. The controller 92 controls the conveyance robot TR3 to cause the three support members P to slide on the three polishing members 43 based on the polishing condition.

In step STf, next, step S63 is performed. In step S63, the dust collection in the target region 41a by the dust collection device 36b is stopped. The controller 92 stops air suction by the exhaust device 39 of the dust collection device 36b and stops air suction in the dust collection pipes 38. Accordingly, the processing of suctioning dust from the suction ports 37 is finished.

In step STf, next, step S64 is performed. In step S64, the conveyance robot TR3 moves the end effector EE31 from the target region 41a of the first polisher 41 of the polishing device 40 to another region. For example, the conveyance robot TR3 retracts the end effector EE31 to proceed to the next step. In a case where the end effector EE31 is moved from the target region 41a in step S64, step STf as the polishing method of the support members P shown in FIG. 10 is finished.

In a case where only the second polisher 46 is selected in the selection condition of the polisher of the polishing condition, the above polishing step including steps S60 to S64 may be performed by replacing the description related to the first polisher 41 with the description related to the second polisher 46. In a case where both of the first polisher 41 and the second polisher 46 are selected in the selection condition of the polisher of the polishing condition, the above polishing step including steps S60 to S64 may be performed after the end of step S64 by replacing the description related to the first polisher 41 with the description related to the second polisher 46.

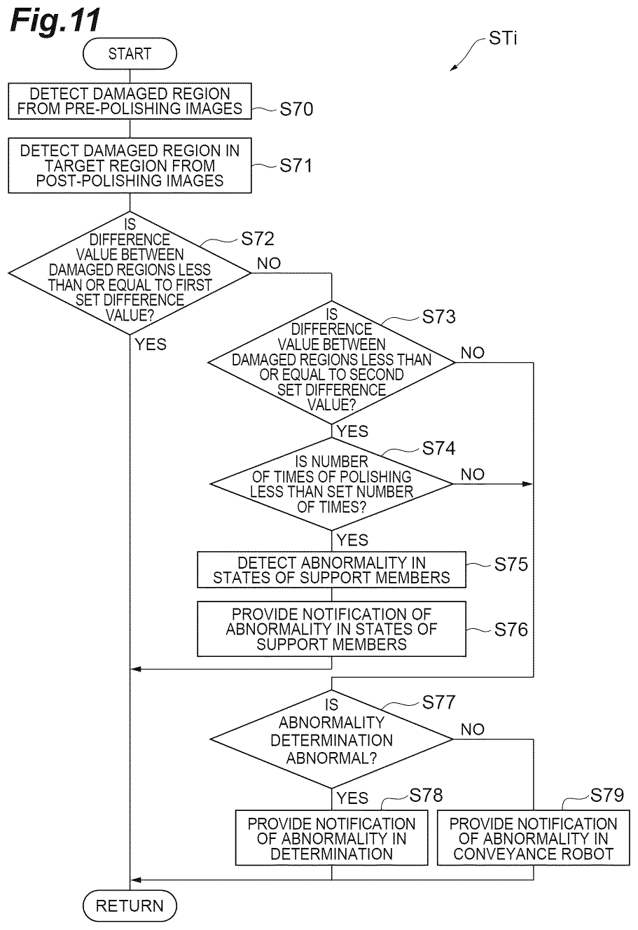

Next, details of the cleaning method performed in the processing system according to one exemplary embodiment will be described with reference to FIG. 11. FIG. 11 is a flowchart of an abnormality detection method by the processing system according to one exemplary embodiment. Hereinafter, details of step STi in the method MT in a case where, for example, the processing system PS is used will be described with reference to FIG. 11. In step STi, the abnormality in the states and the like of the three support members P is detected based on the pre-polishing images and the post-polishing images.

Step STi includes step S70. In step S70, the determiner 93 detects at least one damaged region of the three support members P in the pre-polishing images. In FIG. 11, an example in which one damaged region is detected in one support member P is described.

In step STi, next, step S71 is performed. In step S71, the determiner 93 detects the damaged region in the target region in the post-polishing images at the same position as the damaged region in the pre-polishing images. The determiner 93 detects the target region in the post-polishing images at the same position as the damaged region in the pre-polishing images. The determiner 93 detects the damaged region in the target region. The determiner 93 detects the size of the damaged region. In a case where the determiner 93 does not detect the damaged region in the target region in the post-polishing images at the same position as the damaged region in the pre-polishing images, the determiner 93 sets the size of the damaged region in the target region to 0.

In step STi, next, step S72 is performed. In step S72, the determiner 93 determines whether or not a difference between the size of the damaged region in the pre-polishing images and the size of the damaged region in the target region in the post-polishing images is less than or equal to a first set difference value. The first set difference value is set in advance. In a case where it is determined that the difference is less than or equal to the first set difference value, it is determined that the abnormality in the states of the three support members P is not detected, and step STi as the abnormality detection method shown in FIG. 11 is finished. In a case where it is determined that the difference is not less than or equal to the first set difference value, processing proceeds to step S73.

In step S73, the determiner 93 determines whether or not a difference between the size of the damaged region in the pre-polishing images and the size of the damaged region in the target region in the post-polishing images is less than or equal to a second set difference value. The second set difference value is set in advance. A case where it is determined that the difference is greater than the first set difference value and less than or equal to the second set difference value indicates a state where an effect of the polishing is exhibited but the abnormality in the states of the three support members P is not eliminated. In a case where it is determined that the difference is less than or equal to the second set difference value, the processing proceeds to step S74. A case where it is determined that the difference is greater than the first set difference value and greater than the second set difference value indicates a state where, for example, it is likely that the effect of the polishing is not exhibited and the abnormality has occurred in the cleaning station CL. In a case where it is determined that the difference is not less than or equal to the second set difference value, the processing proceeds to step S77.

In step S74, the determiner 93 determines whether or not the number of times of the polishing after execution of the method MT is less than a set number of times. The set number of times is set in advance. For example, the number of times of the polishing after the execution of the method MT is the same as the number of post-polishing images after the date and time at which the most recent pre-polishing image is acquired. Thus, the determiner 93 acquires the number of post-polishing images as the number of times of the polishing. In a case where it is determined that the number of times of the polishing is less than the set number of times, the processing proceeds to step S75. In a case where it is determined that the number of times of the polishing is not less than the set number of times, the processing proceeds to step S77.

In step S75, the determiner 93 determines that the abnormality in the states of the three support members P is detected. In a case where the abnormality in the state of the at least one support member P among the three support members P is detected, the determiner 93 determines that the state of the support member P is not good.

In step STi, next, step S76 is performed. In step S76, the controller 92 issues an alert indicating that the states of the three support members P are not good. The alert indicating that the states of the three support members P are not good is issued by audio notification using the buzzer (not shown), screen display on the display, and the like.

In step S77, the determiner 93 determines whether or not the abnormality determination in the method MT is abnormal. A case where the abnormality determination is abnormal indicates a state where it is determined that the states of the three support members P are abnormal a predetermined number of times or more because of, for example, an erroneous setting of each threshold value such as the first set difference value, the second set difference value, and the set number of times. In a case where it is determined that the abnormality determination in the method MT is abnormal, the processing proceeds to step S78. The states of the three support members P may be abnormal the predetermined number of times or more even though the abnormality determination is not abnormal. In this case, a state where the abnormality has occurred in the conveyance robot TR3 may occur, such as a case where the conveyance robot TR3 does not move the end effector EE31 to the target region set for each configuration of the cleaning station CL. In a case where it is determined that the abnormality determination in the method MT is not abnormal, the processing proceeds to step S79.

In step S78, the controller 92 provides notification of the abnormality in the abnormality determination. An alert is issued by audio notification using the buzzer (not shown), screen display on the display, and the like. The alert is issued in a different aspect from the alert indicating that the states of the three support members P are not good. After the alert is issued, step STi as the abnormality detection method shown in FIG. 11 is finished.

In step S79, the controller 92 provides notification of the abnormality in the conveyance robot TR3. An alert is issued by audio notification using the buzzer (not shown), screen display on the display, and the like. The abnormality is issued in a different aspect from the alert indicating that the states of the three support members P are not good and the above alert of the abnormality determination. After the alert is issued, step STi as the abnormality detection method shown in FIG. 11 is finished.

### Summary of Embodiment

According to the processing system PS of the embodiment, the at least one support member P on which the substrate W is configured to be mounted can be polished by the polishing device 40. Thus, according to the processing system PS, the support members P supporting the substrate W in the conveyance robot TR3 can be appropriately cleaned. In addition, the polishing device 40 includes a plurality of polishing members 43 and 48 corresponding to each of a plurality of support members P and physically polishes each of the plurality of support members P by the plurality of polishing members 43 and 48. Accordingly, the polishing device 40 can more effectively polish the plurality of support members P.

The conveyance robot TR3 is configured to move the end effector EE31 to the polishing device 40. The end effector EE31 includes the at least one support member P. Thus, the conveyance robot TR3 can move the at least one support member P to the polishing device 40. According to the processing system PS, the support members P supporting the substrate W in the conveyance robot TR3 can be easily cleaned.

In step STe and step STh, the imaging device 50 acquires the images of the at least one support member P at each time before and after the polishing by the polishing device 40 as the pre-polishing images and the post-polishing images of the at least one support member P. In step STi, the determiner 93 determines whether or not the state of the at least one support member P is good based on the pre-polishing images and the post-polishing images acquired by the imaging device 50. According to the processing system PS, a change in the state of the at least one support member P caused by the polishing can be appropriately detected, compared to a case where an operator or the like visually checks the state of the at least one support member P.

The processing system PS further includes the foreign matter removal device 30 that removes the foreign matter attached to the at least one support member P. In step STd, the foreign matter removal device 30 removes the foreign matter of the at least one support member P before the polishing by the polishing device 40. Thus, in step STe, capturing of the foreign matter in the pre-polishing images when acquiring the pre-polishing images is reduced. Furthermore, in step STf, hindering of the polishing by the foreign matter is reduced, and the effect of the polishing by the polishing device 40 is increased. In step STg, the foreign matter removal device 30 removes the foreign matter such as the fine powder and the grit in the at least one support member P after the polishing by the polishing device 40. Thus, in step STh, capturing of the foreign matter in the post-polishing images when acquiring the post-polishing images is reduced. In step STi, the damaged region in the at least one support member P can be appropriately detected, and the abnormality in the state of the at least one support member P can be appropriately detected. In a case where it is determined that the suction force is abnormal, the foreign matter removal device 30 removes the foreign matter in the at least one support member P in step STp. Accordingly, it is suppressed that the suction force is determined to be abnormal due to foreign matter that can be removed by the foreign matter removal device 30.

The foreign matter removal device 30 includes the blowing device 31 and the dust collection device 36. The foreign matter removal device 30 can remove the foreign matter in steps STd, STg, and STp without directly coming into contact with the at least one support member P.

In steps S20 and S24 of step STc, the at least one position measurer 20 measures the position and the inclination of the at least one support member P with respect to the foreign matter removal device 30, the polishing device 40, and the imaging device 50. In steps S23 and S25 of step STc, the conveyance robot TR3 can adjust the position and the inclination of the at least one support member P with respect to the foreign matter removal device 30, the polishing device 40, and the imaging device 50 based on the measured position and inclination of the at least one support member P. In this case, effects of the removal of the foreign matter by the foreign matter removal device 30 in steps STd, STg, and STp and the polishing by the polishing device 40 in step STf can be more appropriately achieved. In addition, by adjusting the position and the inclination of the at least one support member P with respect to the imaging device 50, the pre-polishing images and the post-polishing images acquired by the imaging device 50 in step STe and step STh can be acquired with stable quality. In this case, for example, the position and the inclination of the at least one support member P in the pre-polishing images and the post-polishing images are constant. Thus, the number of steps related to positional alignment and correction of the at least one support member P in the pre-polishing images and the post-polishing images in step STi can be reduced, the at least one support member P can be easily compared, and the damaged region is easily detected.

The conveyance robot TR3 is configured to hold the substrate W by suction on the at least one support member P through air suction from the air suction holes V1 provided in the at least one support member P. The processing system PS includes the at least one suction sensor V5. In step STa and step STk, the determiner 93 detects the abnormality in the state of the at least one support member P by comparing the measured value of the pressure measured by the at least one suction sensor V5 with the threshold value. By holding the substrate W by suction on the at least one support member P through air suction from the air suction holes V1 when the conveyance robot TR3 conveys the substrate W, separation of the substrate W from the end effector EE31 is reduced. In a case where the measured value of the measured pressure is less than the threshold value, it is likely that the substrate W is not appropriately held by suction on the at least one support member P. Thus, by detecting the abnormality in the state of the at least one support member P based on the measured value of the pressure and the threshold value in step STa and step STK, likelihood that the substrate W is not appropriately held by suction on the at least one support member P can be detected early.

In step STa and step STk, the determiner 93 detects the abnormality in the state of the at least one support member P by comparing the time from when the measured value of the pressure measured by the at least one suction sensor V5 is measured to when the measured value of the pressure reaches the threshold value with the set time. In a case where the time from when the measured value of the pressure is measured to when the measured value of the pressure reaches the threshold value is longer than the set time, it is likely that the substrate W is not smoothly held by suction on the at least one support member P and the conveyance robot TR3 cannot smoothly convey the substrate W. Thus, by detecting the abnormality in the state of the at least one support member P in step STa and step STk based on the time and the set time, likelihood that the substrate W is not smoothly held by suction on the at least one support member P can be detected early.

In step S76 in step STi, in a case where the determiner 93 determines that the state of the at least one support member is not good, the controller 92 issues the alert. Accordingly, the processing system PS can appropriately cause the operator or the like to recognize the abnormality in the at least one support member P.

In step STf, in a case where the determiner 93 determines that the state of the at least one support member is not good, the controller 92 polishes the at least one support member P. The abnormality in the suction force of the substrate W in the at least one support member P is detected in step STa, and the abnormality in the at least one support member P is detected in step STi. Since step STf is executed after step STa and step STi, the at least one support member P in which the abnormality is detected can be appropriately polished.

In step STi, the determiner 93 detects the abnormality in the state of the at least one support member P by comparing the difference between the size of the damaged region in the pre-polishing images and the size of the damaged region in the target region in the post-polishing images with the set difference value. Accordingly, the determiner 93 determines whether or not the state of the at least one support member P is good. In this case, how much the damaged region is reduced in the post-polishing images is evaluated with respect to the damaged region in the pre-polishing images through the removal of the foreign matter by the foreign matter removal device 30 in steps STd and STg and the polishing by the polishing device 40 in step STf. In a case where the damaged region is not reduced by a size corresponding to the set difference value, the state of the at least one support member P is detected as being abnormal. Thus, the damaged region in the at least one support member P can be appropriately reduced.

The number of support members P in the conveyance robot TR3 of the processing system PS is not limited to three. The conveyance robot TR3 may include one support member P or may include two or four or more support members P. In step STc, the controller 92 may not control the conveyance robot TR3 to move the end effector EE31 to the target position. In this case, for example, the imaging device 50 may image one support member P to acquire one image for the one support member P by the camera 51. After the one support member P is imaged, the controller 92 may move the end effector EE31 by the conveyance robot TR3 to position another non-imaged support member P directly below the camera 51. The number of cameras 51 in the imaging device 50 is not limited to one, and the imaging device 50 may include three cameras 51. The imaging device 50 may include two or four or more cameras 51.

The number of blowing nozzles 34 provided in the foreign matter removal device 30 and the number of polishing members 43 and 48 provided in the polishing device 40 may correspond to the number of support members P. In step STf, while an aspect in which the conveyance robot TR3 causes the three support members P to slide on the polishing members 43 is shown, the polishing device 40 may be controlled to slide on the three support members P.

The number of position measurers 20 in the processing system PS is not limited to three. The processing system PS may include one position measurer 20 or may include two or four or more position measurers 20. The position and the inclination of the at least one support member with respect to at least one of the foreign matter removal device 30, the polishing device 40, or the imaging device 50 may be measured by only the position measurers 20. The position and the inclination of the at least one support member with respect to at least one of the foreign matter removal device 30, the polishing device 40, or the imaging device 50 may be calculated by the controller 92.

The cleaning device in the processing system PS is not limited to the polishing device 40. The cleaning device only needs to be a device having a function of cleaning the at least one support member P. The processing system PS may include, for example, at least one of a polishing device, a plasma emission device, a blasting device, or a blowing device as the cleaning device. The cleaning device may be the same device as the foreign matter removal device 30.

While various exemplary embodiments are described above, various additions, omissions, substitutions, and changes may be made without being limited to the above exemplary embodiments. Other embodiments can be formed by combining elements in different embodiments.

Here, various exemplary embodiments included in the present disclosure will be described in [E1] to [E16] below.

### [E1]

A processing system including
an atmosphere conveyance module capable of conveying a substrate in an atmosphere,
a conveyance device that includes an end effector including at least one support member on which the substrate is configured to be mounted, is provided in the atmosphere conveyance module, and is configured to convey the substrate, and
a cleaning device that cleans the at least one support member.

### [E2]

The processing system according to [E1],
in which the cleaning device is provided in the atmosphere conveyance module or connected to the atmosphere conveyance module, and
the conveyance device is configured to move the end effector to the cleaning device.

### [E3]

The processing system according to [E1] or [E2], further including
an imaging device that acquires images of the at least one support member at each time before and after cleaning by the cleaning device as a pre-cleaning image and a post-cleaning image of the at least one support member, and
a determiner that determines whether or not a state of the at least one support member is good based on the pre-cleaning image and the post-cleaning image acquired by the imaging device.

### [E4]

The processing system according to any one of [E1] to [E3], further including
a foreign matter removal device that removes foreign matter attached to the at least one support member.

### [E5]

The processing system according to [E4],
in which the foreign matter removal device includes
   a blowing device that removes the foreign matter attached to the at least one support member by air blowing, and
   a dust collection device that collects the foreign matter removed by the blowing device.

### [E6]

The processing system according to any one of [E1] to [E5], further including
at least one position measurer that measures a position and an inclination of the at least one support member with respect to the cleaning device,
in which the conveyance device adjusts the position and the inclination of the at least one support member with respect to the cleaning device based on the position and the inclination of the at least one support member measured by the at least one position measurer.

### [E7]

The processing system according to [E3], further including
at least one position measurer that measures a position and an inclination of the at least one support member with respect to the imaging device,
in which the conveyance device adjusts at least one of the position and/or the inclination of the at least one support member with respect to the imaging device based on the position and the inclination of the at least one support member measured by the at least one position measurer.

### [E8]

The processing system according to [E4] to [E5], further including
at least one position measurer that measures a position and an inclination of the at least one support member with respect to the foreign matter removal device,
in which the conveyance device adjusts the position and the inclination of the at least one support member with respect to the foreign matter removal device based on the position and the inclination of the at least one support member measured by the at least one position measurer.

### [E9]

The processing system according to any one of [E1] to [E8],
in which the conveyance device is configured to hold the substrate by suction on the at least one support member through air suction from an air suction hole provided in the at least one support member, and
the processing system further includes
   at least one pressure measurer that measures a pressure reflecting a suction force of the conveyance device, and
   a determiner that determines whether or not a state of the at least one support member is good by comparing a measured value of the pressure measured by the at least one pressure measurer with a threshold value.

### [E10]

The processing system according to any one of [E1] to [E9],
in which the conveyance device is configured to hold the substrate by suction on the at least one support member through air suction from a hole provided in the at least one support member, and
the processing system further includes
   at least one pressure measurer that measures a pressure reflecting a suction force of the conveyance device, and
   a determiner that determines whether or not a state of the at least one support member is good by comparing a time from when a measured value of the pressure measured by the at least one pressure measurer is measured to when the measured value of the pressure reaches a threshold value with a set time.

### [E11]

The processing system according to [E9] or [E10], further including
a controller that issues an alert in a case where the determiner determines that the state of the at least one support member is not good.

### [E12]

The processing system according to any one of [E9] to [E11],
in which in a case where the determiner determines that the state of the at least one support member is not good, the cleaning device cleans the at least one support member.

### [E13]

The processing system according to any one of [E9] to [E12], further including
a foreign matter removal device that removes foreign matter attached to the at least one support member,
in which in a case where the determiner determines that the state of the at least one support member is not good after the at least one support member is cleaned by the cleaning device, the foreign matter removal device removes the foreign matter attached to the at least one support member.

### [E14]

The processing system according to [E3],
in which the determiner detects at least one damaged region of the at least one support member in the pre-cleaning image and, in a case where at least one damaged region is detected in at least one target region in the post-cleaning image at the same position as the at least one damaged region in the pre-cleaning image, determines whether or not the state of the at least one support member is good by comparing a difference between a size of the at least one damaged region in the pre-cleaning image and a size of the at least one damaged region in the at least one target region in the post-cleaning image with a set difference value.

### [E15]

The processing system according to [E14], further including
a controller that issues an alert in a case where the determiner determines that the difference between the sizes of the at least one damaged region in each of the pre-cleaning image and the post-cleaning image is greater than the set difference value.

### [E16]

The processing system according to any one of [E1] to [E15],
in which the end effector includes a plurality of support members as the at least one support member, and
the cleaning device includes a plurality of polishing members corresponding to each of the plurality of support members and physically polishes each of the plurality of support members by the plurality of polishing members.

From the above description, it will be understood that various embodiments of the present disclosure are described in the present specification for descriptive purposes and various modifications may be made without departing from the scope and the gist of the present disclosure. Accordingly, various embodiments disclosed in the present specification are not intended to be limiting, and the true scope and gist are shown by the accompanying claims. The present disclosure encompasses various modifications to each of the examples and embodiments discussed herein. According to the disclosure, one or more features described above in one embodiment or example can be equally applied to another embodiment or example described above. The features of one or more embodiments or examples described above can be combined into each of the embodiments or examples described above. Any full or partial combination of one or more embodiment or examples of the invention is also part of the disclosure.

### REFERENCE SIGNS LIST

10: substrate mount
20: position measurer
30: foreign matter removal device
31: blowing device
36, 36a, 36b, 36c: dust collection device
40: polishing device
43, 48: polishing member
50: imaging device
92: controller
93: determiner
AN: aligner
CL: cleaning station
CU: control device
EE11, EE12, EE21, EE22, EE31: end effector
FK11, FK12, FK21, FK22, FK31: fork
LL1, LL2: load lock module
LM: loader module
LP1 to LP4: load port
MT: cleaning method
P: support member
PS: processing system
SR: storage
TR1, TR2, TR3: conveyance robot
V1: air suction hole
V2: suction path
V3: exhaust pipe
V4: exhaust device
V5: suction sensor
W: substrate

What is claimed is:

1. A processing system comprising:
an atmosphere conveyance module capable of conveying a substrate in an atmosphere;
a conveyance device that includes an end effector including at least one support member on which the substrate is configured to be mounted, is provided in the atmosphere conveyance module, and is configured to convey the substrate; and
a cleaning device that cleans the at least one support member.

2. The processing system according to claim 1,
wherein the cleaning device is provided in the atmosphere conveyance module or connected to the atmosphere conveyance module, and
the conveyance device for moving the end effector to the cleaning device.

3. The processing system according to claim 1, further comprising:
an imaging device that acquires images of the at least one support member at each time before and after cleaning by the cleaning device as a pre-cleaning image and a post-cleaning image of the at least one support member; and
determiner circuitry a determiner that determines whether or not a state of the at least one support member is good based on the pre-cleaning image and the post-cleaning image acquired by the imaging device.

4. The processing system according to claim 1, further comprising:
a foreign matter removal device that removes foreign matter attached to the at least one support member.

5. The processing system according to claim 4,
wherein the foreign matter removal device includes:
a blowing device that removes the foreign matter attached to the at least one support member by air blowing; and
a dust collection device that collects the foreign matter removed by the blowing device.

6. The processing system according to claim 1, further comprising:
at least one position measurer that measures a position and an inclination of the at least one support member with respect to the cleaning device,
wherein the conveyance device adjusts the position and the inclination of the at least one support member with respect to the cleaning device based on the position and the inclination of the at least one support member measured by the at least one position measurer.

7. The processing system according to claim 3, further comprising:
at least one position measurer that measures a position and an inclination of the at least one support member with respect to the imaging device,
wherein the conveyance device adjusts at least one of the position and/or the inclination of the at least one support member with respect to the imaging device based on the position and the inclination of the at least one support member measured by the at least one position measurer.

8. The processing system according to claim 4, further comprising:
at least one position measurer that measures a position and an inclination of the at least one support member with respect to the foreign matter removal device,
wherein the conveyance device adjusts the position and the inclination of the at least one support member with respect to the foreign matter removal device based on the position and the inclination of the at least one support member measured by the at least one position measurer.

9. The processing system according to claim 1,
wherein the conveyance device is configured to hold the substrate by suction on the at least one support member through air suction from an air suction hole provided in the at least one support member, and
the processing system further includes:
at least one pressure measurer that measures a pressure reflecting a suction force of the conveyance device; and
determiner circuitry that determines whether or not a state of the at least one support member is good by comparing a measured value of the pressure measured by the at least one pressure measurer with a threshold value.

10. The processing system according to claim 1,
wherein the conveyance device is configured to hold the substrate by suction on the at least one support member through air suction from an air suction hole provided in the at least one support member, and
the processing system further includes:
at least one pressure measurer that measures a pressure reflecting a suction force of the conveyance device; and
determiner circuitry that determines whether or not a state of the at least one support member is good by comparing a time from when a measured value of the pressure measured by the at least one pressure measurer is measured to when the measured value of the pressure reaches a threshold value with a set time.

11. The processing system according to claim 9, further comprising:
controller circuitry configured to issue an alert in a case where the determiner circuitry determines that the state of the at least one support member is not good.

12. The processing system according to claim 9,
wherein in a case where the determiner circuitry determines that the state of the at least one support member is not good, the cleaning device cleans the at least one support member.

13. The processing system according to claim 9, further comprising:
a foreign matter removal device that removes foreign matter attached to the at least one support member,
wherein in a case where the determiner circuitry determines that the state of the at least one support member is not good after the at least one support member is cleaned by the cleaning device, the foreign matter removal device removes the foreign matter attached to the at least one support member.

14. The processing system according to claim 3,
wherein the determiner circuitry detects at least one damaged region of the at least one support member in the pre-cleaning image and, in a case where at least one damaged region is detected in at least one target region in the post-cleaning image at the same position as the at least one damaged region in the pre-cleaning image, determines whether or not the state of the at least one support member is good by comparing a difference between a size of the at least one damaged region in the pre-cleaning image and a size of the at least one damaged region in the at least one target region in the post-cleaning image with a set difference value.

15. The processing system according to claim 14, further comprising:
controller circuitry configured to issue an alert in a case where the determiner circuitry determines that the difference between the sizes of the at least one damaged region in each of the pre-cleaning image and the post-cleaning image is greater than the set difference value.

16. The processing system according to claim 1,
wherein the end effector includes a plurality of support members as the at least one support member, and
the cleaning device includes a plurality of polishing members corresponding to each of the plurality of support members and physically polishes each of the plurality of support members by the plurality of polishing members.

17. A non-transitory computer-readable medium storing instructions that, when executed by a processor of a control device in a processing system, cause the processor to:
control a conveyance device to convey a substrate in an atmosphere conveyance module, the conveyance device including an end effector with at least one support member supporting the substrate; and
control a cleaning device to clean the at least one support member.

18. The non-transitory computer-readable medium of claim 17, wherein the instructions further cause the processor to detect an abnormality in a suction force of the conveyance device based on pressure measurements.

19. The non-transitory computer-readable medium of claim 18, wherein the instructions further cause the processor to control an imaging device to acquire images of the at least one support member before and after cleaning.

20. A method of cleaning a support member in a processing system, the method comprising:
conveying a substrate using a conveyance device in an atmosphere conveyance module, the conveyance device including an end effector with at least one support member supporting the substrate;
detecting an abnormality in a suction force of the conveyance device based on pressure measurements; and
cleaning the at least one support member using a cleaning device.
